(19) United States
(12) Patent Application Publication
(10) Pub. No.: US 2026/0020332 A1
(43) Pub. Date: Jan. 15, 2026

(54) SEMICONDUCTOR DEVICE

(71) Applicant: Samsung Electronics Co., Ltd., Suwon-si (KR)

(72) Inventor: MYOUNG-SUN LEE, Suwon-si (KR)

(21) Appl. No.: 19/048,174

(22) Filed: Feb. 7, 2025

(30) Foreign Application Priority Data
Jul. 15, 2024 (KR) 10-2024-0092831

(51) Int. Cl. H10D 84/83; H10D 30/00; H10D 30/01; H10D 62/10; H10D 62/13; H10D 64/23; H10D 84/01

(52) U.S. Cl. CPC H10D 84/832; H10D 30/506; H10D 62/121; H10D 62/151; H10D 64/256; H10D 84/8312; H10D 30/0194; H10D 84/0151

(57) ABSTRACT

A semiconductor device includes a first fin pattern extending in a first direction, source/drain patterns on the first fin pattern, a gate electrode extending in a second direction, an insulating structure in contact with the first fin pattern, a lower conductive pattern and an upper conductive pattern overlapping the insulating structure in a third direction, and a connection contact extending through the insulating structure and electrically connecting the lower conductive pattern and the upper conductive pattern. The first fin pattern includes a first fin portion, a second fin portion spaced apart from the first fin portion, and a third fin portion between the first fin portion and the second fin portion. A width in the second direction of the first fin portion and a width in the second direction of the second fin portion are greater than a width in the second direction of the third fin portion.

### CROSS-REFERENCE TO RELATED APPLICATIONS

This U.S. non-provisional patent application claims priority under 35 U.S.C. § 119 of Korean Patent Application No. 10-2024-0092831, filed on Jul. 15, 2024, the entire contents of which are hereby incorporated by reference.

### BACKGROUND

The present disclosure herein relates to a semiconductor device, and more particularly, to a semiconductor device including a fin pattern.

A semiconductor device includes an integrated circuit composed of metal-oxide-semiconductor field effect transistors (MOSFET). As a size of the semiconductor device gradually decreases, scaling down of the metal-oxide-semiconductor field effect transistors may be gradually accelerated. As the metal-oxide-semiconductor field effect transistors are gradually scaled down, operation characteristics of the semiconductor device may be deteriorated. Accordingly, research on various methods of overcoming limitation caused by high-integration of the semiconductor device and forming the semiconductor device for better performance is being conducted.

### SUMMARY

The present disclosure provides a semiconductor device with improved electrical characteristics and reliability and a method for manufacturing the same.

An embodiment of the inventive concept provides a semiconductor device including a first fin pattern extending in a first direction, source/drain patterns on the first fin pattern, a gate electrode extending in a second direction that intersects the first direction, an insulating structure in contact with the first fin pattern, a lower conductive pattern and an upper conductive pattern overlapping the insulating structure in a third direction that is perpendicular to the first and second direction, and a connection contact extending through the insulating structure and electrically connecting the lower conductive pattern and the upper conductive pattern, wherein the first fin pattern includes a first fin portion, a second fin portion spaced apart from the first fin portion in the first direction, and a third fin portion between the first fin portion and the second fin portion, wherein a width in the second direction of the first fin portion and a width in the second direction of the second fin portion are greater than a width in the second direction of the third fin portion, the insulating structure is between the first fin portion and the second fin portion, and the insulating structure is in contact with the first fin portion, the second fin portion, and the third fin portion.

In an embodiment of the inventive concept, a semiconductor device includes a first fin pattern extending in a first direction, a gate electrode extending in a second direction that intersects the first direction, an insulating structure in contact with the first fin pattern, a lower conductive pattern and an upper conductive pattern overlapping the insulating structure in a third direction that is perpendicular to the first and second directions, a connection contact extending through the insulating structure and electrically connecting the lower conductive pattern and the upper conductive pattern, and a first source/drain pattern, a second source/drain pattern and a third source/drain pattern on the first fin pattern, wherein the third source/drain pattern is between the first source/drain pattern and the second source/drain pattern, and the third source/drain pattern is in contact with the insulating structure.

In an embodiment of the inventive concept, a semiconductor device includes a first fin pattern extending in a first direction, a second fin pattern spaced apart from the first fin pattern in a second direction that intersects the first direction, a gate electrode extending in the second direction, source/drain patterns on the first and second fin patterns, an insulating structure between the first fin pattern and the second fin pattern, a lower conductive pattern and an upper conductive pattern overlapping the insulating structure in a third direction that is perpendicular to the first and second directions, a connection contact extending through the insulating structure and electrically connecting the lower conductive pattern and the upper conductive pattern, and a first isolation structure and a second isolation structure on the first fin pattern, wherein the insulating structure, the connection contact and the upper conductive pattern are between the first isolation structure and the second isolation structure, and the insulating structure is in contact with the first fin pattern and the second fin pattern.

### BRIEF DESCRIPTION OF THE FIGURES

The accompanying drawings are included to provide a further understanding of the inventive concept and are incorporated in and constitute a part of this specification. The drawings illustrate embodiments of the inventive concept and, together with the description, serve to explain principles of the inventive concept. In the drawings:

FIG. 1A is a plan view of a semiconductor device according to some embodiments;

FIG. 1B is a cross-sectional view taken along line A-A′ of FIG. 1A;

FIG. 1C is a cross-sectional view taken along line B-B′ of FIG. 1A;

FIG. 1D is a cross-sectional view taken along line C-C′ of FIG. 1A;

FIG. 1E is a cross-sectional view taken along line D-D′ of FIG. 1A;

FIG. 1F is an enlarged view taken along region ‘Q1’ of FIG. 1A;

FIG. 1G is a diagram for describing fin patterns and an insulating structure of a semiconductor device according to FIG. 1A;

FIGS. 2A, 2B, 3A, 3B, 3C, 3D, 4A, 4B, 4C, 4D, 5A, 5B, 5C and 5D are diagrams for describing a method for manufacturing a semiconductor device according to some embodiments;

FIG. 6A is an enlarged cross-sectional view of a semiconductor device according to some embodiments;

FIGS. 6B and 6C are cross-sectional views of a semiconductor device according to FIG. 6A;

FIG. 7A is an enlarged cross-sectional view of a semiconductor device according to some embodiments;

FIG. 7B is a cross-sectional view of a semiconductor device according to FIG. 7A;

FIG. 8 is a plan view illustrating fin patterns and an insulating structure of a semiconductor device according to some embodiments;

FIG. 9 is a plan view of a semiconductor device according to some embodiments;

FIG. 10 is a plan view of a semiconductor device according to some embodiments; and

FIG. 11 is a plan view of a semiconductor device according to some embodiments.

### DETAILED DESCRIPTION

As used herein, the terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present.

Components or layers described with reference to “overlap” in a particular direction may be at least partially obstructed by one another when viewed along a line extending in the particular direction or in a plane perpendicular to the particular direction. The term “surrounding” or “covering” or “filling” or “penetrating” as may be used herein may not require completely surrounding or covering or filling or penetrating the described elements or layers, but may, for example, refer to partially surrounding or covering or filling or penetrating the described elements or layers, for example, with voids or other spaces throughout.

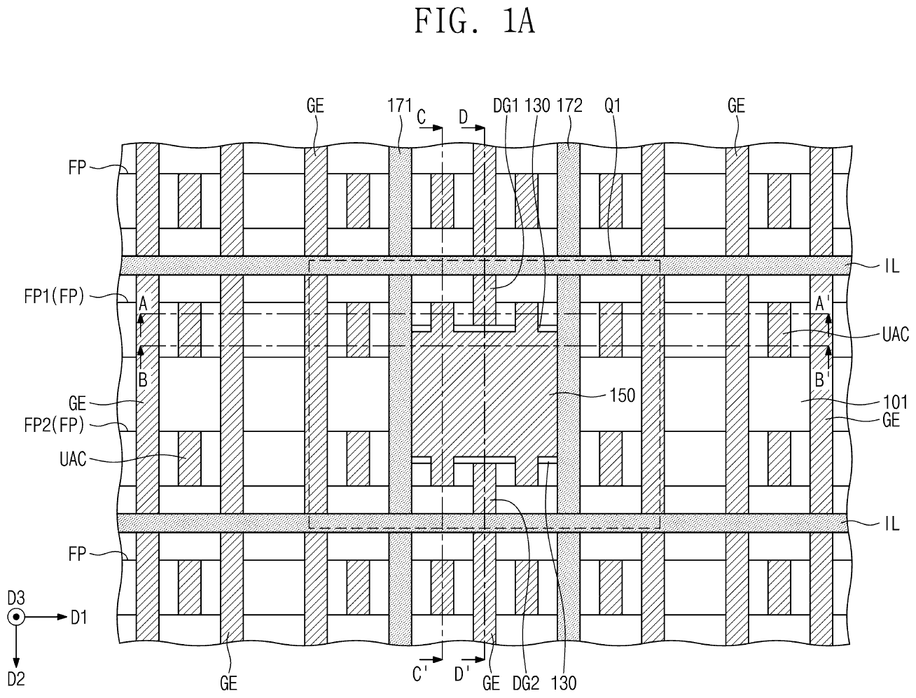

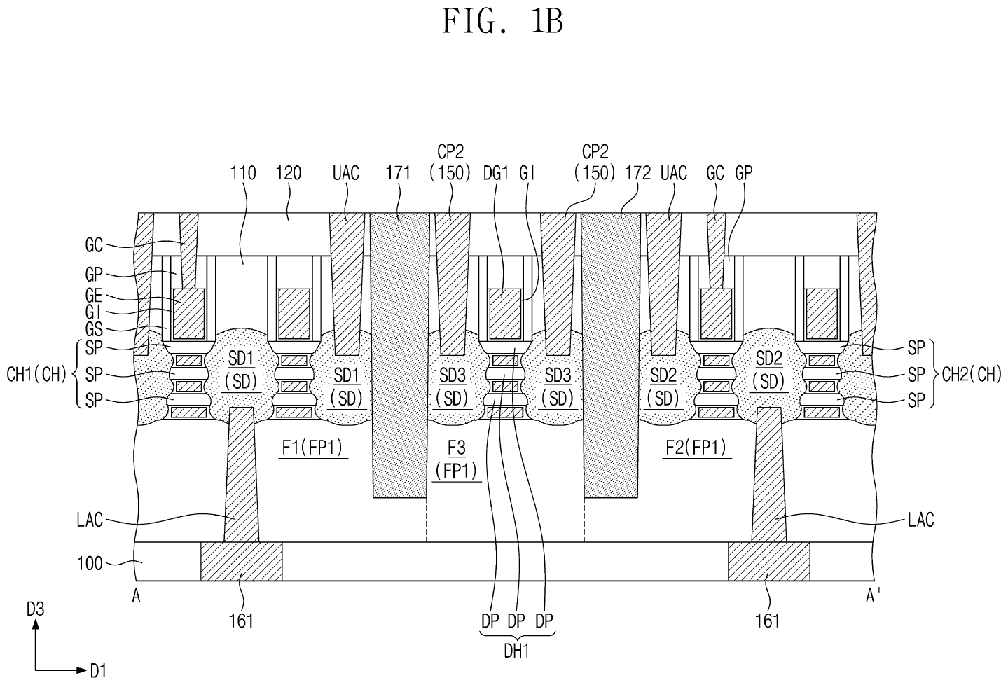

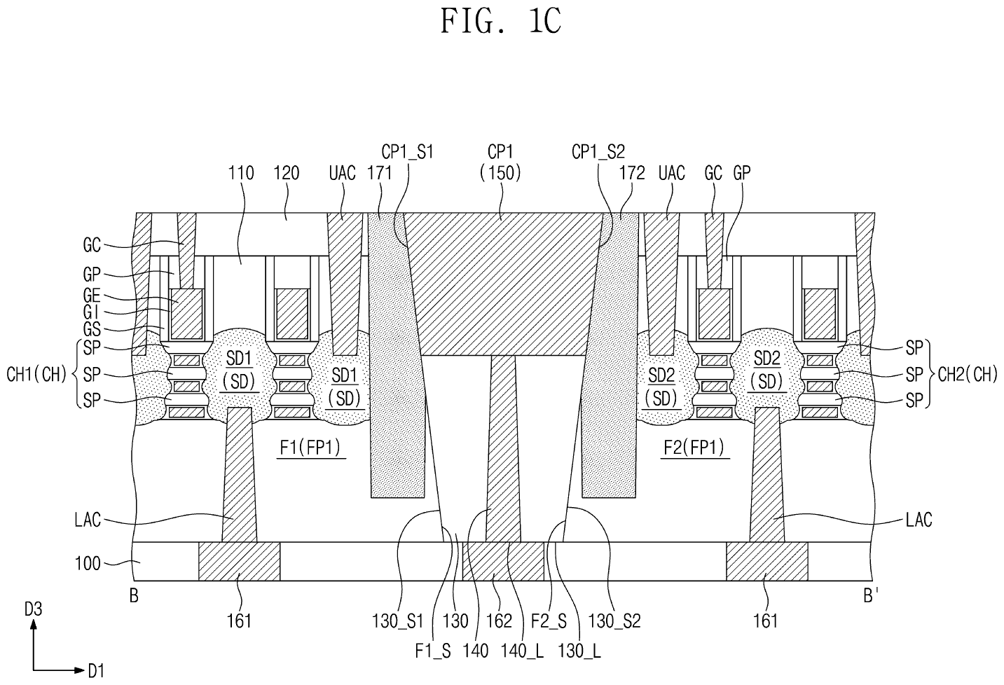

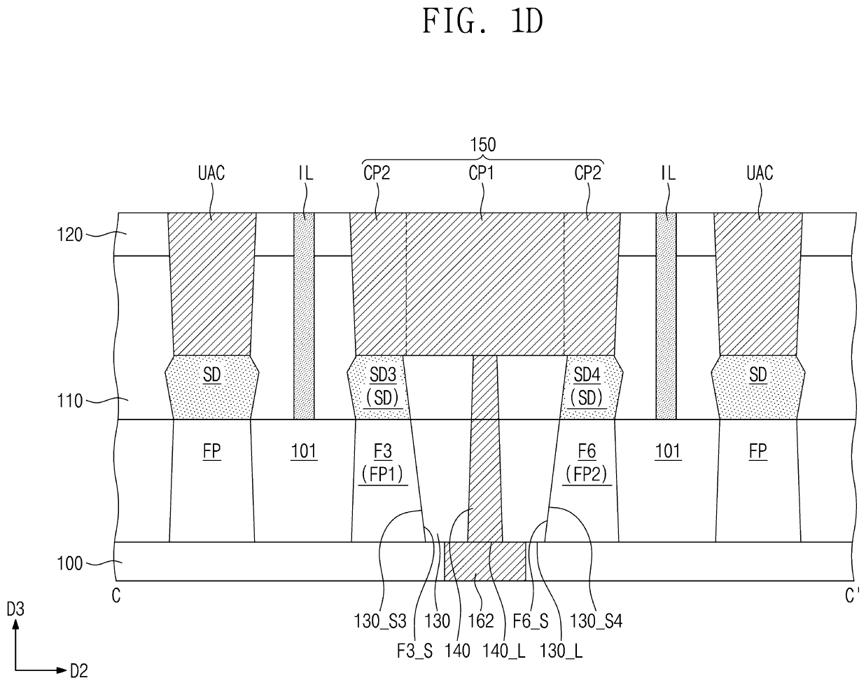

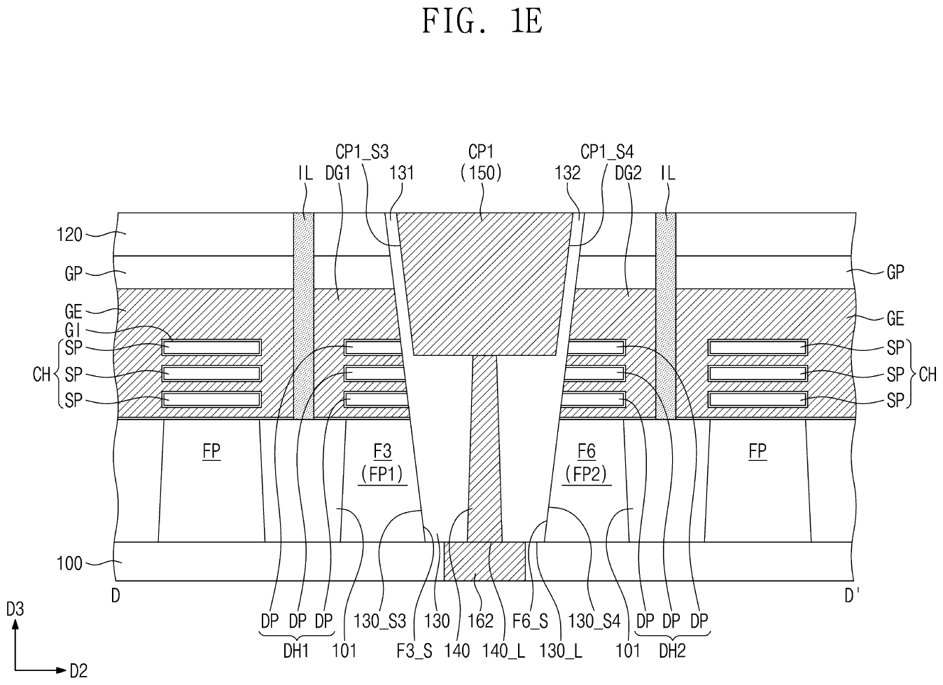

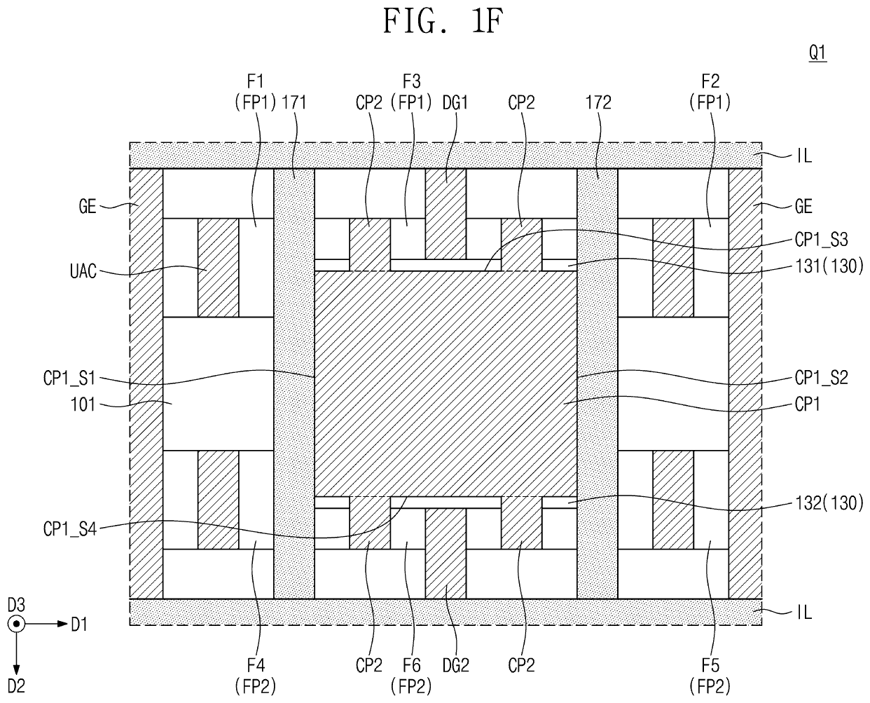

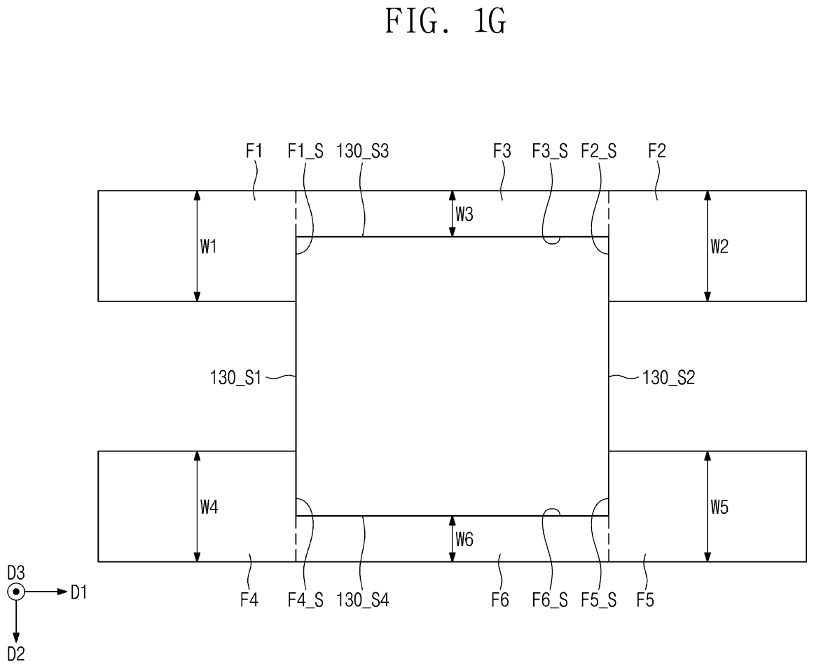

FIG. 1A is a plan view of a semiconductor device according to some embodiments. FIG. 1B is a cross-sectional view taken along line A-A′ of FIG. 1A. FIG. 1C is a cross-sectional view taken along line B-B′ of FIG. 1A. FIG. 1D is a cross-sectional view taken along line C-C′ of FIG. 1A. FIG. 1E is a cross-sectional view taken along line D-D′ of FIG. 1A. FIG. 1F is an enlarged view taken along region ‘Q1’ of FIG. 1A. FIG. 1G is a diagram for describing fin patterns and an insulating structure of a semiconductor device according to FIG. 1A.

Referring to FIGS. 1A to 1E, the semiconductor device may include a lower insulating film 100. The lower insulating film 100 may include an insulating material. According to some embodiments, the lower insulating film 100 may be a multiple film including a plurality of insulating films.

The lower insulating film 100 may have a form of a plate extending along a plane extending in a first direction D1 and a second direction D2. The first direction D1 and the second direction D2 may cross each other. For example, the first direction D1 and the second direction D2 may be horizontal directions perpendicular to each other.

Fin patterns FP may be provided on the lower insulating film 100. The fin patterns FP may extend in the first direction D1. The fin patterns FP may be arranged spaced apart from each other in the second direction D2. The fin patterns FP may include a first fin pattern FP1 and a second fin pattern FP2 adjacent to each other in the second direction D2. According to some embodiments, a transistor on the first fin pattern FP1 may be an NMOSFET, and a transistor on the second fin pattern FP2 may be a PMOSFET. According to some embodiments, a transistor on the first fin pattern FP1 may be a PMOSFET, and a transistor on the second fin pattern FP2 may be an NMOSFET.

The fin patterns FP may include a semiconductor material. For example, the semiconductor material may be silicon. According to some embodiments, a semiconductor substrate may be provided on the lower insulating film 100, and the fin patterns FP may be parts, of the semiconductor substrate, protruding in a third direction D3. In this case, the fin patterns FP may be connected to each other by a lower portion of the semiconductor substrate. According to some embodiments, the fin patterns FP may include an insulating material.

The third direction D3 may cross the first direction D1 and the second direction D2. For example, the third direction D3 may be a vertical direction that is perpendicular to the first direction D1 and the second direction D2.

An element isolation film 101 may be provided. The element isolation film 101 may surround the fin patterns FP. The fin patterns FP may be spaced apart from each other by the element isolation film 101. The element isolation film 101 may include an insulating material. For example, the element isolation film 101 may include an oxide.

Source/drain patterns SD may be provided on the fin patterns FP. The source/drain patterns SD may be each an epitaxial pattern formed in a selective epitaxial growth (SEG) process. The source/drain patterns SD may include a semiconductor material. For example, the source/drain patterns SD may include at least one of silicon (Si), silicon-germanium (SiGe), or germanium (Ge). The source/drain patterns SD may be doped with an impurity.

Channel structures CH may be provided. The channel structure CH may overlap the fin pattern FP in the third direction D3. The channel structure CH may include semiconductor patterns SP overlapping each other in the third direction D3. The semiconductor patterns SP may include, for example, silicon or silicon-germanium.

Gate electrodes GE may be provided. A gate electrode GE may cross the fin pattern FP. The gate electrode GE may overlap the fin pattern FP in the third direction D3. The gate electrode GE may extend in the second direction D2. The gate electrode GE and the semiconductor patterns SP of the channel structures CH may constitute a three-dimensional field effect transistor (for example, a MBCFET or GAAFET).

Gate isolation films IL may be provided. The gate isolation films IL may extend in the first direction D1. The gate isolation films IL may be disposed between the gate electrodes GE. The gate isolation films IL may include an insulating material. For example, the gate isolation films IL may include a nitride.

Gate insulating films GI may be provided. The gate insulating film GI may be in contact with the gate electrode GE or dummy gate electrodes DG1 and DG2 to be described later. The gate insulating film GI may include an insulating material. For example, the gate insulating film GI may include an oxide.

Gate spacers GS may be provided. A pair of gate spacers GS may be disposed on both sides of the gate electrode GE or the dummy gate electrode DG1 or DG2. The gate spacers GS may extend in the second direction D2. The upper surfaces of the gate spacers GS may be coplanar with an upper surface of a first interlayer insulating layer 110 to be described later. The gate spacers GS may include an insulating material.

Gate capping patterns GP may be provided. The gate capping pattern GP may be provided on the gate electrode GE or the dummy gate electrode DG1 or DG2. The gate capping pattern GP may extend in the second direction D2. The gate capping pattern GP may include an insulating material.

The first interlayer insulating layer 110 may be provided. The first interlayer insulating layer 110 may be provided on the source/drain patterns SD and the gate spacers GS. A second interlayer insulating layer 120 may be provided on the first interlayer insulating layer 110. The second interlayer insulating layer 120 may be provided on the first interlayer insulating layer 110, the gate spacers GS and the gate capping patterns GP. The first and second interlayer insulating layers 110 and 120 may include an insulating material. For example, the first and second interlayer insulating layers 110 and 120 may include an oxide.

Upper active contacts UAC and lower active contacts LAC may be provided. The upper active contact UAC and the lower active contact LAC may be each electrically connected to the source/drain pattern SD. The upper active contact UAC may penetrate the first and second interlayer insulating layers 110 and 120 to be connected to an upper portion of the source/drain pattern SD. The lower active contact LAC may penetrate the fin pattern FP to be connected to a lower portion of the source/drain pattern SD. The upper active contact UAC and the lower active contact LAC may include a conductive material.

Gate contacts GC may be provided. The gate contact GC may be electrically connected to the gate electrode GE. The gate contact GC may penetrate the second interlayer insulating layer 120 and the gate capping pattern GP. The gate contact GC may include a conductive material.

An insulating structure 130 may be provided. The insulating structure 130 may be provided between the first fin pattern FP1 and the second fin pattern FP2. The insulating structure 130 may be in contact with the first fin pattern FP1 and the second fin pattern FP2. The insulating structure 130 may include an insulating material. For example, the insulating structure 130 may include an oxide. According to some embodiments, the insulating structure 130 may be a multiple film including a plurality of insulating films.

A connection contact 140 extending through the insulating structure 130 may be provided. The connection contact 140 may be surrounded by the insulating structure 130. The connection contact 140 may include a conductive material.

An upper conductive pattern 150 may be provided on the insulating structure 130. The upper conductive pattern 150 may overlap the insulating structure 130 in the third direction D3. First lower conductive patterns 161 and second lower conductive pattern 162 in the lower insulating film 100 may be provided. The first lower conductive pattern 161 may be electrically connected to the lower active contact LAC. An upper surface of the first lower conductive pattern 161 may be in contact with a lower surface of the lower active contact LAC. The second lower conductive pattern 162 may be electrically connected to the connection contact 140. An upper surface of the second lower conductive pattern 162 may be in contact with a lower surface 140_L of the connection contact 140 and a lower surface 130_L of the insulating structure 130. The connection contact 140 may electrically connect the upper conductive pattern 150 and the second lower conductive pattern 162. The first and second lower conductive patterns 161 and 162 may be disposed at a lower level than the fin patterns FP. The upper conductive pattern 150 may be disposed at the same level as the upper active contact UAC. The upper conductive pattern 150 may include the same conductive material as the upper active contact UAC.

A first isolation structure 171 and a second isolation structure 172 may be provided. The insulating structure 130, the connection contact 140 and the upper conductive pattern 150 may be disposed between the first isolation structure 171 and the second isolation structure 172. The first and second isolation structures 171 and 172 may extend in the second direction D2. The first and second isolation structures 171 and 172 may penetrate the second interlayer insulating layer 120 and the first interlayer insulating layer 110. The first and second isolation structures 171 and 172 may be disposed on the fin patterns FP and the element isolation film 101. The first and second isolation structures 171 and 172 may include an insulating material. A lower surface of the first isolation structure 171 and a lower surface of the second isolation structure 172 may have higher levels than the lower surface 130_L of the insulating structure 130.

A first dummy gate electrode DG1 and a second dummy gate electrode DG2 may be provided between the first and second isolation structures 171 and 172. The first and second dummy gate electrodes DG1 and DG2 may be spaced apart from each other in the second direction D2. The insulating structure 130, the connection contact 140 and the upper conductive pattern 150 may be provided between the first and second dummy gate electrodes DG1 and DG2. The first and second dummy gate electrodes DG1 and DG2 may be provided between the gate isolation films IL. The first and second dummy gate electrodes DG1 and DG2 may include the same conductive material as the gate electrode GE. A length in the second direction D2 of each of the first and second dummy gate electrodes DG1 and DG2 may be shorter than a length in the second direction D2 of the gate electrode GE.

A first dummy channel structure DH1 and a second dummy channel structure DH2 may be provided between the first and second isolation structures 171 and 172. The first and second dummy channel structures DH1 and DH2 may be spaced apart from each other in the second direction D2. The insulating structure 130, the connection contact 140 and the upper conductive pattern 150 may be provided between the first and second dummy channel structures DH1 and DH2. The first and second dummy channel structures DH1 and DH2 may be provided between the gate isolation films IL.

The first and second dummy channel structures DH1 and DH2 may each include dummy semiconductor patterns DP overlapping each other in the third direction D3. The dummy semiconductor patterns DP may include the same material as the semiconductor patterns SP. A width in the second direction D2 of each of the first and second dummy channel structures DH1 and DH2 may be smaller than a width in the second direction D2 of the channel structure CH. A width in the second direction D2 of the dummy semiconductor pattern DP may be smaller than a width in the second direction D2 of the semiconductor pattern SP.

Referring to FIGS. 1B, 1C, 1D, 1E, 1F and 1G, the first fin pattern FP1 may include a first fin portion F1, a second fin portion F2 and a third fin portion F3. The first fin portion F1 and the second fin portion F2 may be spaced apart from each other in the first direction D1. The third fin portion F3 may be disposed between the first fin portion F1 and the second fin portion F2. The third fin portion F3 may connect the first fin portion F1 and the second fin portion F2.

A width W1 in the second direction D2 of the first fin portion F1 and a width W2 in the second direction D2 of the second fin portion F2 may be greater than a width W3 in the second direction D2 of the third fin portion F3. A maximum width in the second direction D2 of the first fin portion F1 and a maximum width in the second direction D2 of the second fin portion F2 may be greater than a maximum width in the second direction D2 of the third fin portion F3.

A sidewall F1_S of the first fin portion F1 may be in contact with a first sidewall 130_S1 of the insulating structure 130. A sidewall F2_S of the second fin portion F2 may be in contact with a second sidewall 130_S2 of the insulating structure 130. A sidewall F3_S of the third fin portion F3 may be in contact with a third sidewall 130_S3 of the insulating structure 130.

The first sidewall 130_S1 and the second sidewall 130_S2 of the insulating structure 130 may be opposed to each other. The sidewall F1_S of the first fin portion F1 and the sidewall F2_S of the second fin portion F2 may be spaced apart from each other. The sidewall F3_S of the third fin portion F3 may be connected to the sidewall F1_S of the first fin portion F1 and the sidewall F2_S of the second fin portion F2. The insulating structure 130 may be disposed between the first fin portion F1 and the second fin portion F2.

The second fin pattern FP2 may include a fourth fin portion F4, a fifth fin portion F5 and a sixth fin portion F6. The fourth fin portion F4 and the fifth fin portion F5 may be spaced apart from each other in the first direction D1. The sixth fin portion F6 may be disposed between the fourth fin portion F4 and the fifth fin portion F5. The sixth fin portion F6 may connect the fourth fin portion F4 and the fifth fin portion F5.

A width W4 in the second direction D2 of the fourth fin portion F4 and a width W5 in the second direction D2 of the fifth fin portion F5 may be greater than a width W6 in the second direction D2 of the sixth fin portion F6. A maximum width in the second direction D2 of the fourth fin portion F4 and a maximum width in the second direction D2 of the fifth fin portion F5 may be greater than a maximum width in the second direction D2 of the sixth fin portion F6.

A sidewall F4_S of the fourth fin portion F4 may be in contact with the first sidewall 130_S1 of the insulating structure 130. A sidewall F5_S of the fifth fin portion F5 may be in contact with the second sidewall 130_S2 of the insulating structure 130. A sidewall F6_S of the sixth fin portion F6 may be in contact with a fourth sidewall 130_S4 of the insulating structure 130. The fourth sidewall 130_S4 of the insulating structure 130 may be opposed to the third sidewall 130_S3 of the insulating structure 130.

The third sidewall 130_S3 of the insulating structure 130 may connect the first sidewall 130_S1 and the second sidewall 130_S2 of the insulating structure 130. The fourth sidewall 130_S4 of the insulating structure 130 may connect the first sidewall 130_S1 and the second sidewall 130_S2 of the insulating structure 130. A distance in the first direction D1 between the first and second sidewalls 130_S1 and 130_S2 of the insulating structure 130 may become smaller with decrease of levels thereof. A distance in the second direction D2 between the third and fourth sidewalls 130_S3 and 130_S4 of the insulating structure 130 may become smaller with decrease of levels thereof. The third sidewall 130_S3 and the fourth sidewall 130_S4 of the insulating structure 130 may be respectively in contact with a sidewall of the second interlayer insulating layer 120 and a sidewall of the gate capping pattern GP.

The sidewall F4_S of the fourth fin portion F4 and the sidewall F5_S of the fifth fin portion F5 may be spaced apart from each other. The sidewall F6_S of the sixth fin portion F6 may be connected to the sidewall F4_S of the fourth fin portion F4 and the sidewall F5_S of the fifth fin portion F5. The insulating structure 130 may be disposed between the fourth fin portion F4 and the fifth fin portion F5.

The insulating structure 130 may be disposed between the third fin portion F3 and the sixth fin portion F6. A width in the second direction D2 of the insulating structure 130 may be greater than a width in the second direction D2 of each of the first and second fin patterns FP1 and FP2. A width in the second direction D2 of the first sidewall 130_S1 of the insulating structure 130 may be greater than a sum of a width in the second direction D2 of the sidewall F1_S of the first fin portion F1 and a width in the second direction D2 of the sidewall F4_S of the fourth fin portion F4. A width in the second direction D2 of the second sidewall 130_S2 of the insulating structure 130 may be greater than a sum of a width in the second direction D2 of the sidewall F2_S of the second fin portion F2 and a width in the second direction D2 of the sidewall F5_S of the fifth fin portion F5.

The lower surface 130_L of the insulating structure 130 may be disposed at the same level as a lower surface of each of the first to sixth fin portions F1 to F6.

The source/drain patterns SD may include first source/drain patterns SD1 on the first fin portion F1, second source/drain patterns SD2 on the second fin portion F2, third source/drain patterns SD3 on the third fin portion F3, and fourth source/drain patterns SD4 on the sixth fin portion F6.

The third source/drain patterns SD3 may be disposed between the first and second source/drain patterns SD1 and SD2, and between the first and second isolation structures 171 and 172. The fourth source/drain patterns SD4 may be disposed between the first and second isolation structures 171 and 172.

The insulating structure 130 and the connection contact 140 may be disposed between the third and fourth source/drain patterns SD3 and SD4. A width in the second direction D2 of the first source/drain pattern SD1 and a width in the second direction D2 of the second source/drain pattern SD2 may be greater than a width in the second direction D2 of the third source/drain pattern SD3. The third source/drain pattern SD3 may be in contact with the third sidewall 130_S3 of the insulating structure 130. A width in the second direction D2 of the first source/drain pattern SD1 and a width in the second direction D2 of the second source/drain pattern SD2 may be greater than a width in the second direction D2 of the fourth source/drain pattern SD4. The fourth source/drain pattern SD4 may be in contact with the fourth sidewall 130_S4 of the insulating structure 130.

The first dummy gate electrode DG1 may be disposed between the third source/drain patterns SD3. The first dummy gate electrode DG1 may overlap the third fin portion F3 in the third direction D3. The first dummy gate electrode DG1 may be in contact with the third sidewall 130_S3 of the insulating structure 130.

The second dummy gate electrode DG2 may be disposed between the fourth source/drain patterns SD4. The second dummy gate electrode DG2 may overlap the sixth fin portion F6 in the third direction D3. The second dummy gate electrode DG2 may be in contact with the fourth sidewall 130_S4 of the insulating structure 130.

The gate insulating films GI may include a gate insulating film GI in contact with the third sidewall 130_S3 of the insulating structure 130 and the first dummy gate electrode DG1. The gate insulating films GI may include a gate insulating film GI in contact with the fourth sidewall 130_S4 of the insulating structure 130 and the second dummy gate electrode DG2.

The channel structures CH may include first channel structures CH1 overlapping the first fin portion F1 in the third direction D3 and second channel structures CH2 overlapping the second fin portion F2 in the third direction D3.

The first dummy channel structure DH1 may overlap the first dummy gate electrode DG1 and the third fin portion F3 in the third direction D3. The first dummy channel structure DH1 may be disposed between the first channel structure CH1 and the second channel structure CH2. Sidewalls of the dummy semiconductor patterns DP of the first dummy channel structure DH1 may be in contact with the third sidewall 130_S3 of the insulating structure 130.

The second dummy channel structure DH2 may overlap the second dummy gate electrode DG2 and the sixth fin portion F6 in the third direction D3. The sidewalls of the dummy semiconductor patterns DP of the second dummy channel structure DH2 may be in contact with the fourth sidewall 130_S4 of the insulating structure 130.

The upper conductive pattern 150 may include a first pattern portion CP1 and second pattern portions CP2. The second pattern portion CP2 may protrude from the first pattern portion CP1. The second pattern portion CP2 may protrude from the first pattern portion CP1 in the second direction D2 or an opposite direction of the second direction D2. The first pattern portion CP1 may be disposed between the second pattern portions CP2 spaced apart from each other in the second direction D2.

A lower surface of the first pattern portion CP1 may be in contact with an upper surface of the connection contact 140. The second pattern portion CP2 may be in contact with the third source/drain pattern SD3 or the fourth source/drain pattern SD4. A lower surface of the second pattern portion CP2 may be in contact with the third source/drain pattern SD3 or the fourth source/drain pattern SD4.

A first sidewall CP1_S1 of the first pattern portion CP1 may be in contact with the first isolation structure 171. A second sidewall CP1_S2 of the first pattern portion CP1 may be in contact with the second isolation structure 172. The first sidewall CP1_S1 and the second sidewall CP1_S2 of the first pattern portion CP1 may be opposed to each other.

A third sidewall CP1_S3 and a fourth sidewall CP1_S4 of the first pattern portion CP1 may be in contact with the insulating structure 130. The third sidewall CP1_S3 and the fourth sidewall CP1_S4 of the first pattern portion CP1 may be opposed to each other. The insulating structure 130 may include a first part 131 between the third sidewall CP1_S3 of the first pattern portion CP1 and the first dummy gate electrode DG1. The insulating structure 130 may include a second part 132 between the fourth sidewall CP1_S4 of the first pattern portion CP1 and the second dummy gate electrode DG2.

According to some embodiments, the third sidewall CP1_S3 of the first pattern portion CP1 may be in contact with the first dummy gate electrode DG1. In this case, the insulating structure 130 may not include the first part 131 between the third sidewall CP1_S3 of the first pattern portion CP1 and the first dummy gate electrode DG1.

According to some embodiments, the fourth sidewall CP1_S4 of the first pattern portion CP1 may be in contact with the second dummy gate electrode DG2. In this case, the insulating structure 130 may not include the second part 132 between the fourth sidewall CP1_S4 of the first pattern portion CP1 and the second dummy gate electrode DG2.

A width in the first direction D1 of the first pattern portion CP1 may be greater than a width in the first direction D1 of the second pattern portion CP2. A width in the second direction D2 of the first pattern portion CP1 may be greater than a width in the second direction D2 of the second pattern portion CP2. Two second pattern portions CP2 may protrude from the third sidewall CP1_S3 of the first pattern portion CP1. The two second pattern portions CP2 protruding from the third sidewall CP1_S3 of the first pattern portion CP1 may be spaced apart from each other in the first direction D1. Two second pattern portions CP2 may protrude from the fourth sidewall CP1_S4 of the first pattern portion CP1. The two second pattern portions CP2 protruding from the fourth sidewall CP1_S4 of the first pattern portion CP1 may be spaced apart from each other in the first direction D1.

Since in the semiconductor device according to some embodiments the first fin pattern FP1 includes the third fin portion F3, and the second fin pattern FP2 includes the sixth fin portion F6, where the third fin portion F3 and the sixth fin portion F6 are in contact with the insulating structure 130, the element isolation film 101 may be omitted between the first fin portion F1 and the second fin portion F2, and between the fourth fin portion F4 and the fifth fin portion F5. Accordingly, a phenomenon that a tensile stress occurs due to the element isolation film 101 between the first fin portion F1 and the second fin portion F2, and between the fourth fin portion F4 and the fifth fin portion F5 may be prevented or limited.

Since the phenomenon that the tensile stress occurs is prevented or limited, a phenomenon that threshold voltages of transistors on the first, second, fourth and fifth fin portions F1, F2, F4 and F5 increase due to the tensile stress may be prevented or limited, and electrical characteristics of the transistors around a region in which the insulating structure 130 and the connection contact 140 are disposed may be improved.

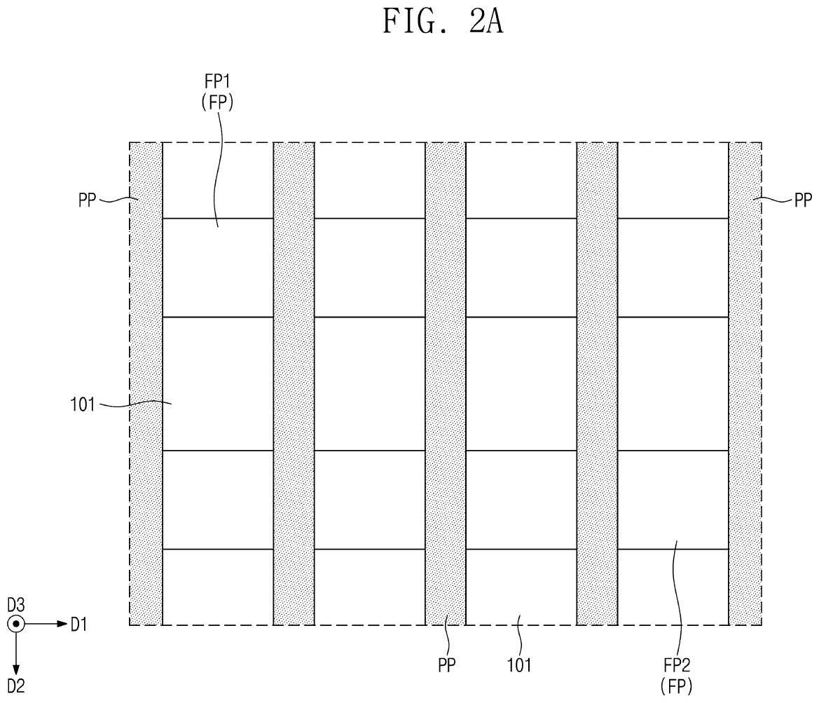

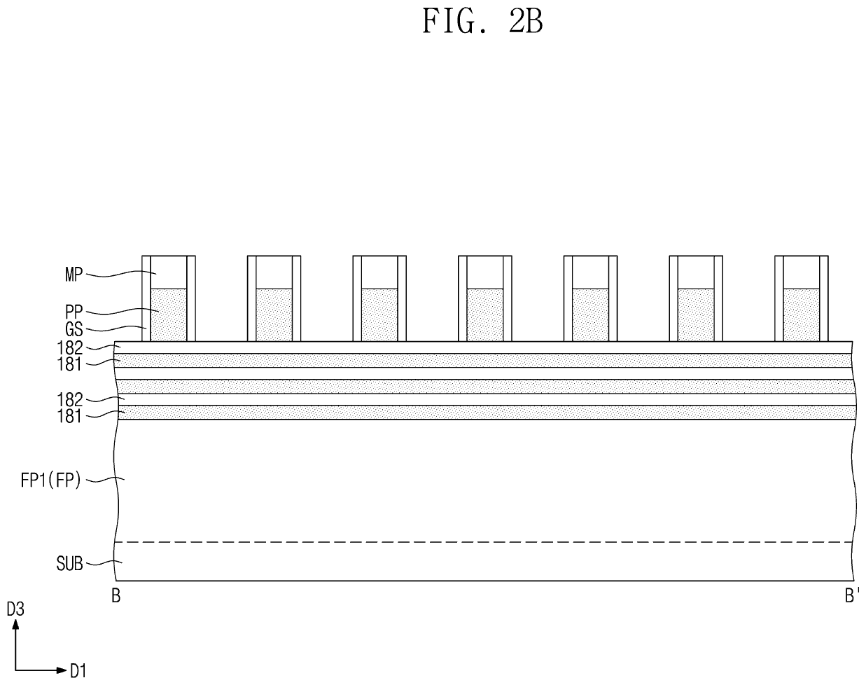

FIGS. 2A, 2B, 3A, 3B, 3C, 3D, 4A, 4B, 4C, 4D, 5A, 5B, 5C and 5D are diagrams for describing a method for manufacturing a semiconductor device according to some embodiments.

Referring to FIGS. 2A and 2B, a substrate SUB may be provided. Fin patterns FP, sacrificial films 181 and semiconductor films 182 may be formed. Forming fin patterns FP, sacrificial films 181, and semiconductor films 182 may include alternately forming preliminary sacrificial films and preliminary semiconductor films on the substrate SUB, and patterning the preliminary sacrificial films and the preliminary semiconductor films and the substrate SUB.

The sacrificial films 181 may be formed by patterning the preliminary sacrificial films. The semiconductor films 182 may be formed by patterning the preliminary semiconductor films. The fin patterns FP may be formed by patterning the substrate SUB.

The sacrificial film 181 may include a material having etching selectivity for the semiconductor film 182. For example, the sacrificial film 181 may include silicon-germanium, and the semiconductor film 182 may include silicon. An element isolation film 101 may be formed.

Sacrificial patterns PP and mask patterns MP may be formed. Forming the sacrificial patterns PP and the mask patterns MP may include forming a preliminary pattern film, forming the mask patterns MP on the preliminary pattern film, and patterning the preliminary pattern film by using the mask patterns MP as etching masks. The sacrificial patterns PP may be formed by patterning the preliminary pattern film. For example, the sacrificial patterns PP may include polysilicon. The mask patterns MP may include an insulating material.

Gate spacers GS may be formed. The gate spacers GS may be formed on sidewalls of the sacrificial pattern PP and the mask pattern MP.

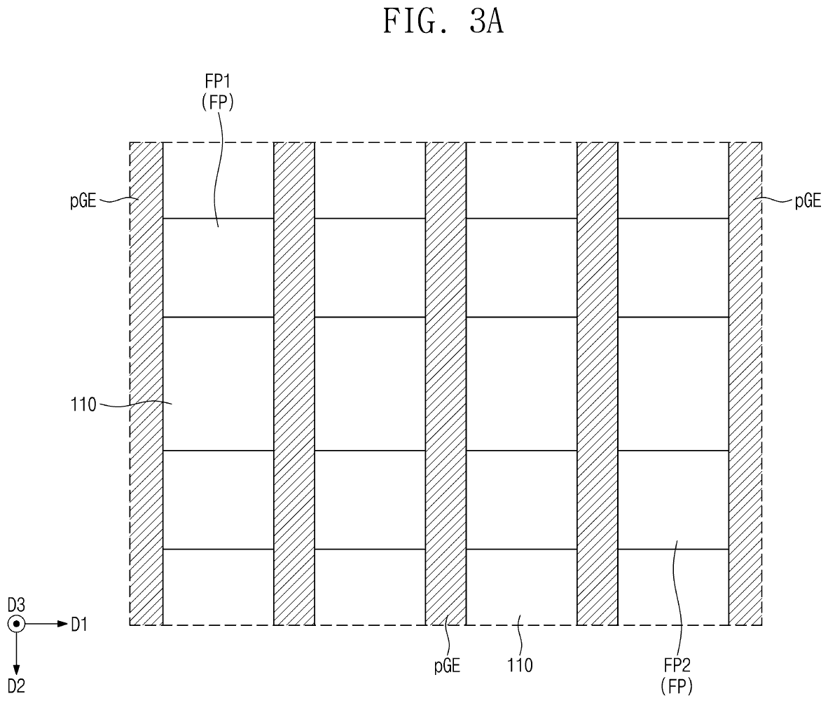

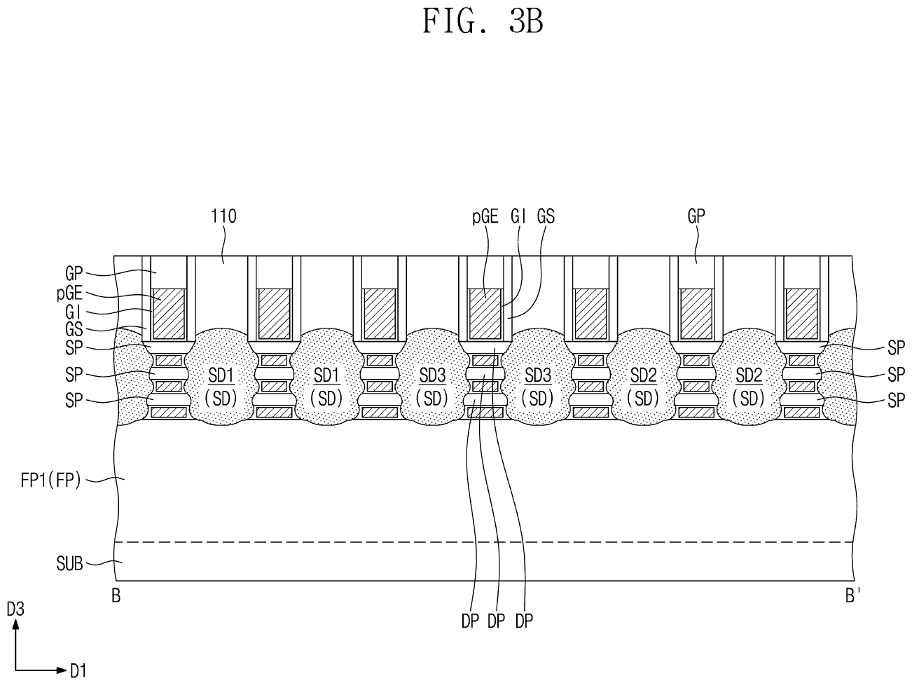

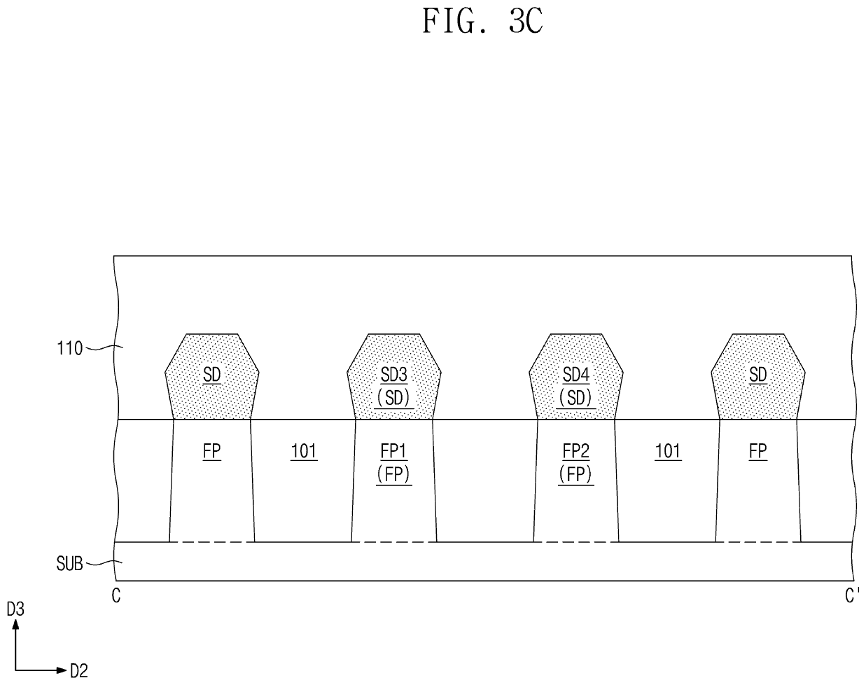

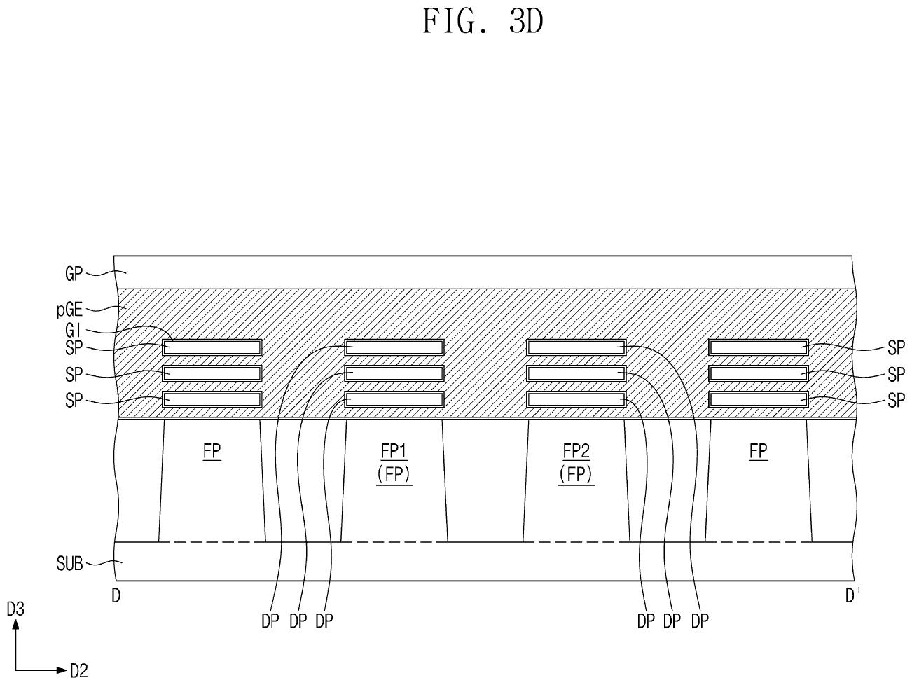

Referring to FIGS. 3A, 3B, 3C, and 3D, the sacrificial films 181 and the semiconductor films 182 may be etched by using the mask patterns MP and the gate spacers GS as etching masks. Semiconductor patterns SP and dummy semiconductor patterns DP may be formed by etching the semiconductor films 182.

Source/drain patterns SD may be formed. The source/drain patterns SD may be formed through an epitaxial growth process by using the semiconductor patterns SP, the dummy semiconductor patterns DP and the etched sacrificial films 181 as seeds. A first interlayer insulating layer 110 may be formed.

The sacrificial films 181, the mask patterns MP and the sacrificial patterns PP may be removed. Gate insulating films GI, preliminary gate electrodes pGE and gate capping patterns GP may be formed in empty spaces formed by removing the sacrificial films 181, the mask patterns MP and the sacrificial patterns PP. The preliminary gate electrode pGE may include a conductive material. The preliminary gate electrode pGE may be formed between the source/drain patterns SD. The preliminary gate electrodes pGE may extend in the second direction D2.

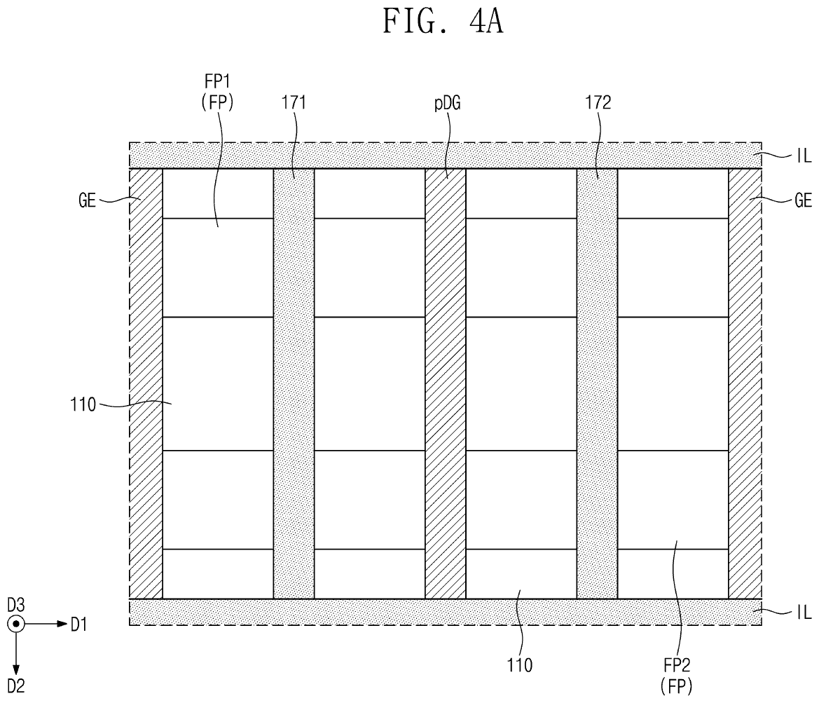

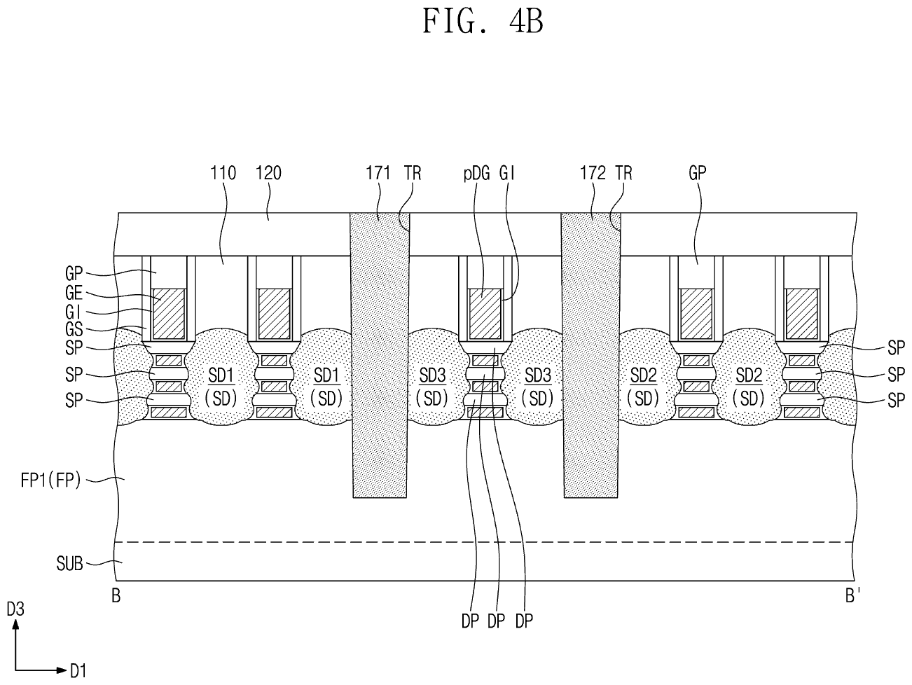

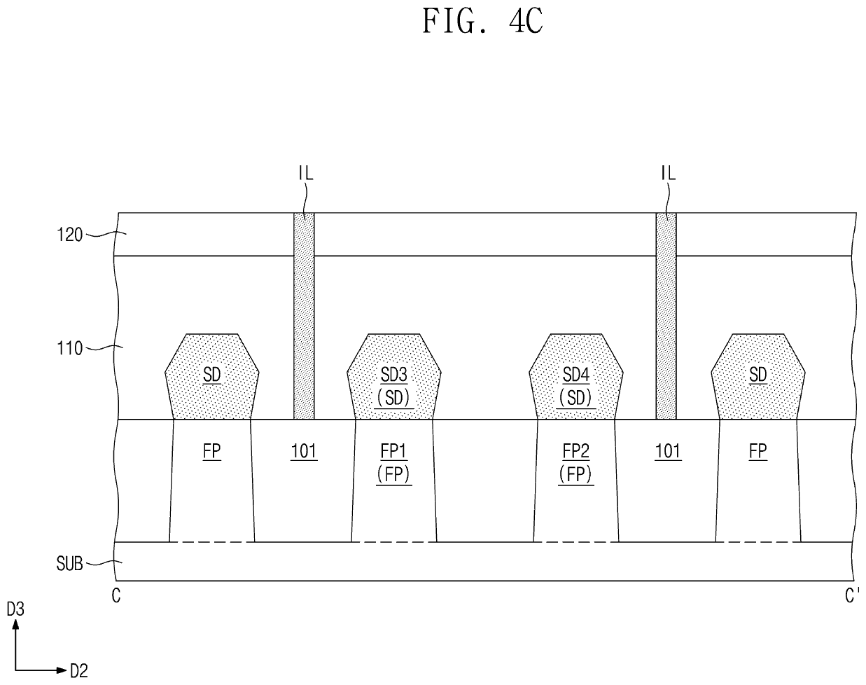

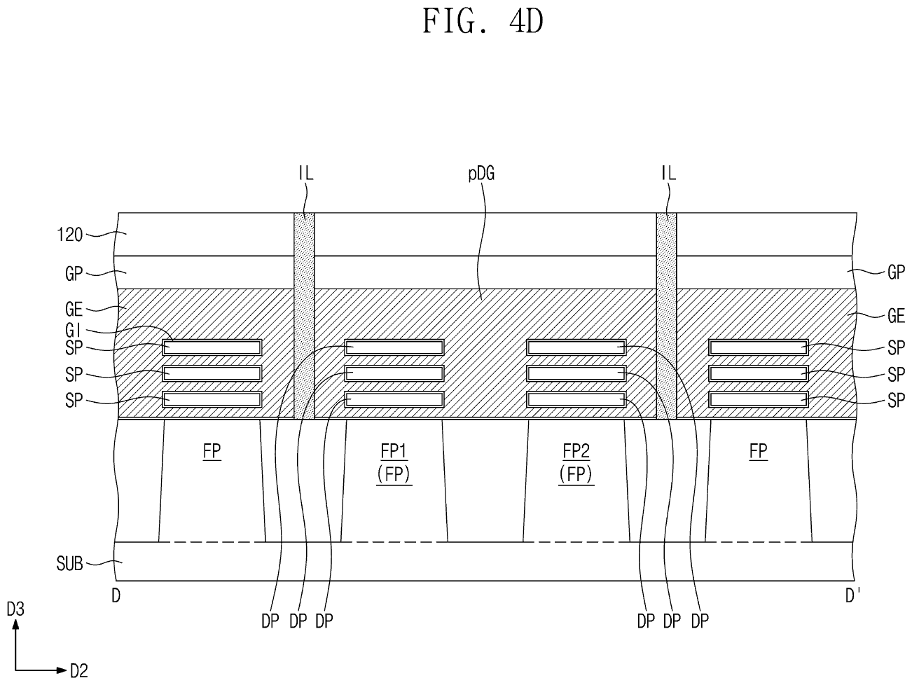

Referring to FIGS. 4A, 4B, 4C, and 4D, a second interlayer insulating layer 120 may be formed. A first isolation structure 171 and a second isolation structure 172 may be formed. Forming the isolation structures 171 and 172 may include forming trenches TR extending in the second direction D2, and forming the isolation structures 171 and 172 in the trenches TR. Forming the trench TR may include removing one of the preliminary gate electrodes pGE, and the gate spacer GS, the gate insulating film GI, the gate capping pattern GP and the semiconductor patterns SP adjacent to one of the preliminary gate electrodes pGE.

Gate isolation films IL may be formed. The preliminary gate electrode pGE may be separated by the gate isolation films IL. The preliminary gate electrode pGE may be separated to form the gate electrode GE and a preliminary dummy gate electrode pDG. The preliminary dummy gate electrode pDG may be disposed between the first and second isolation structures 171 and 172. The preliminary dummy gate electrode pDG may be disposed between the gate isolation films IL.

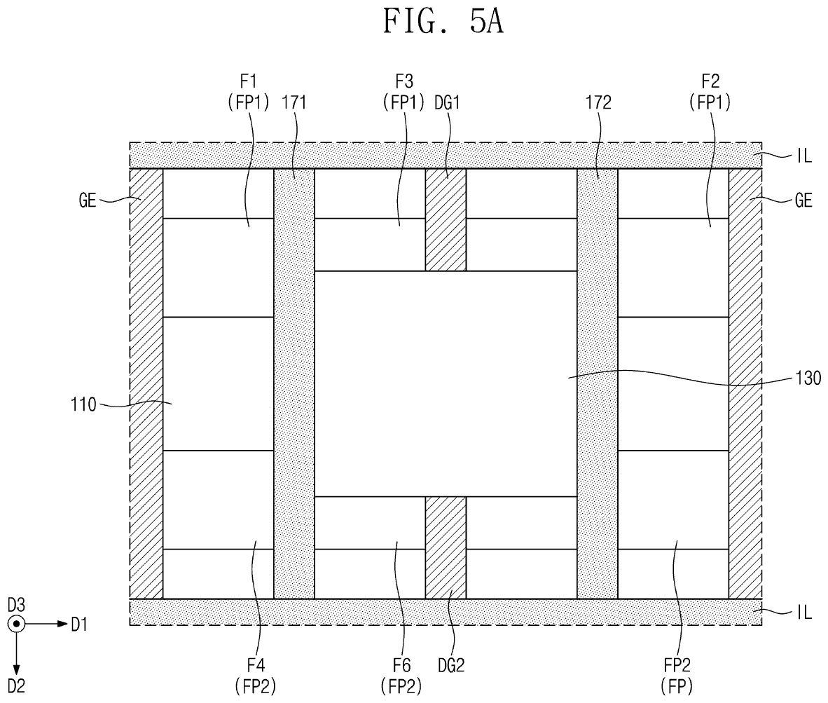

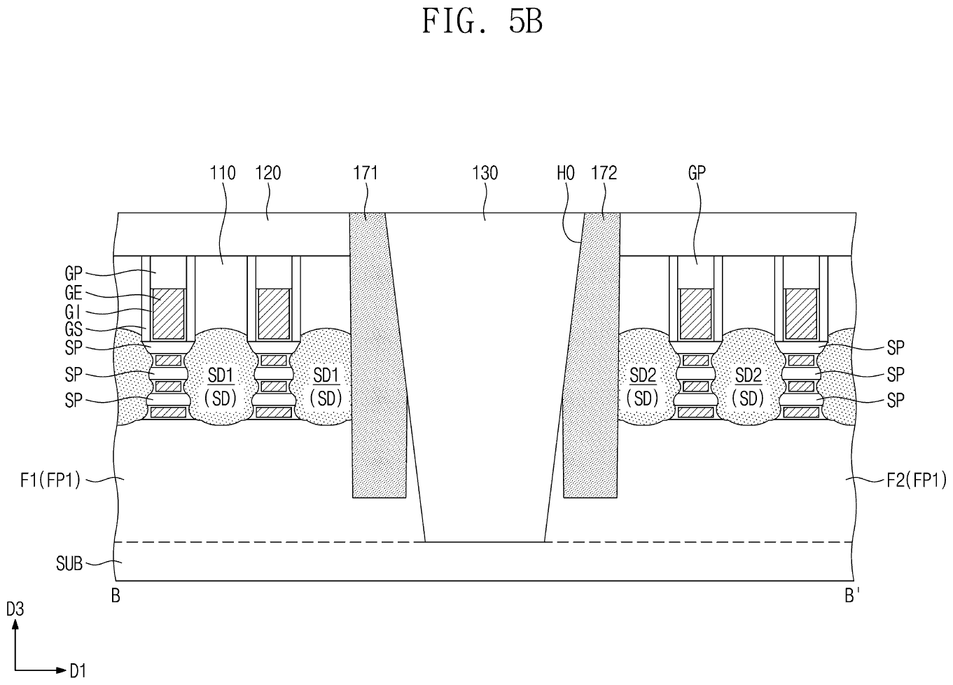

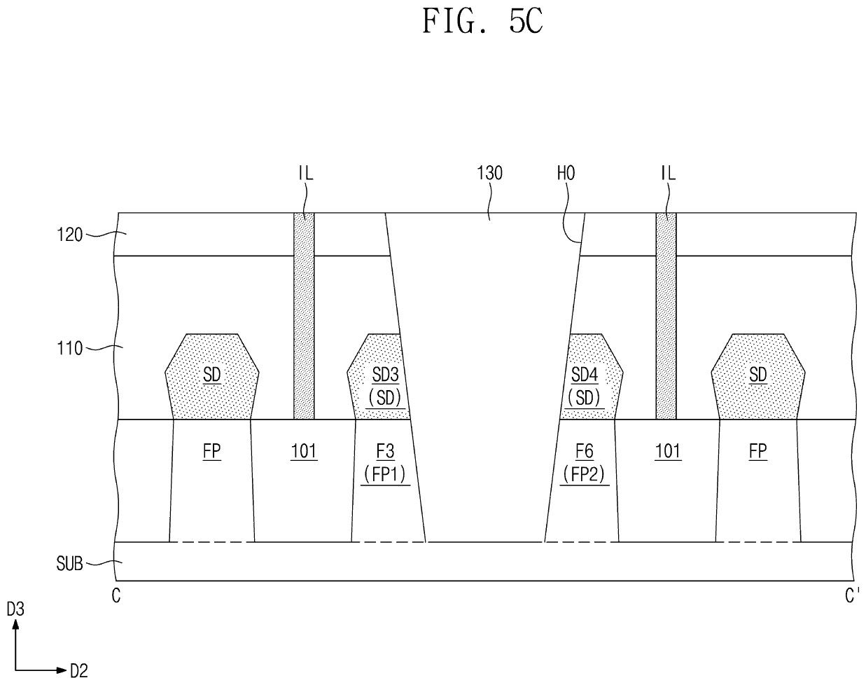

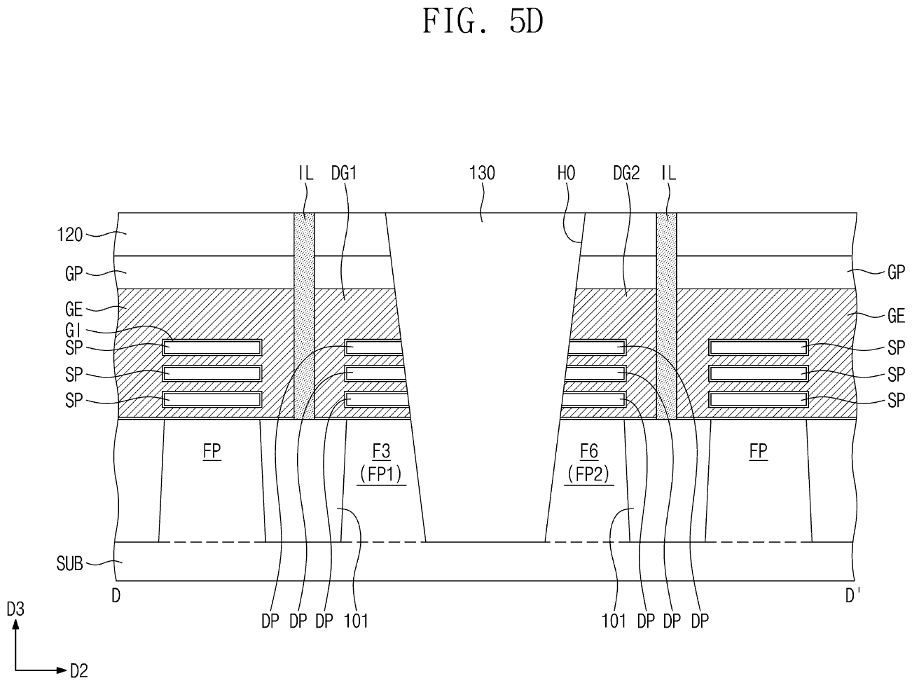

Referring to FIGS. 5A, 5B, 5C and 5D, a hole HO may be formed. The hole HO may be formed between a first fin pattern FP1 and a second fin pattern FP2. Forming the hole HO may include etching the first isolation structure 171, the second isolation structure 172, the second interlayer insulating layer 120, the gate capping pattern GP, the third source/drain pattern SD3, the fourth source/drain pattern SD4, the first interlayer insulating layer 110, the first fin pattern FP1, the second fin pattern FP2, the gate insulating film GI, the dummy semiconductor patterns DP, the preliminary dummy gate electrode pDG and the element isolation film 101.

The etched third source/drain pattern SD3 may be exposed by the hole HO. The etched fourth source/drain pattern SD4 may be exposed by the hole HO. The gate insulating film GI surrounding the dummy semiconductor pattern DP may be etched so that the dummy semiconductor pattern DP may be exposed by the hole HO.

The preliminary dummy gate electrode pDG may be etched to be separated into a first dummy gate electrode DG1 and a second dummy gate electrode DG2. The first and second dummy gate electrodes DG1 and DG2 may be exposed by the hole HO. The etched first isolation structure 171 may be exposed by the hole HO. The etched second isolation structure 172 may be exposed by the hole HO.

The first fin pattern FP1 may be etched to define a first fin portion F1, a second fin portion F2 and a third fin portion F3. The first fin portion F1, the second fin portion F2 and the third fin portion F3 may be exposed by the hole HO.

The second fin pattern FP2 may be etched to define a fourth fin portion F4, a fifth fin portion F5 and a sixth fin portion F6. The fourth fin portion F4, the fifth fin portion F5 and the sixth fin portion F6 may be exposed by the hole HO.

An insulating structure 130 may be formed in the hole HO. The insulating structure 130 may fill the hole HO.

Referring to FIGS. 1A to 1F, upper active contacts UAC and an upper conductive pattern 150 may be formed. The upper active contacts UAC and the upper conductive pattern 150 may be simultaneously formed. Forming the upper conductive pattern 150 may include etching the insulating structure 130 and forming the upper conductive pattern 150 in an empty space formed by etching the insulating structure 130.

A lower portion of the substrate SUB may be removed. The fin patterns FP may be separated by removing the lower portion of the substrate SUB. According to some embodiments, empty spaces formed by removing the fin patterns FP may be filled with insulating films. In this case, the insulating films with which the empty spaces formed by removing the fin patterns FP are filled may be defined as the fin patterns FP.

Lower active contacts LAC penetrating the fin patterns FP may be formed. A lower insulating film 100 may be formed. First lower conductive patterns 161 and second lower conductive pattern 162 may be formed in the lower insulating film 100.

In the method for manufacturing a semiconductor device according to some embodiments, the insulating structure 130 may be formed in a state in which the first fin pattern FP1 and the second fin pattern FP2 are not cut. Accordingly, a leaning phenomenon of the sacrificial patterns PP in a portion in which the first fin pattern FP1 and the second fin pattern

FP2 are cut may be prevented, and stability of a process of manufacturing a semiconductor device may be improved.

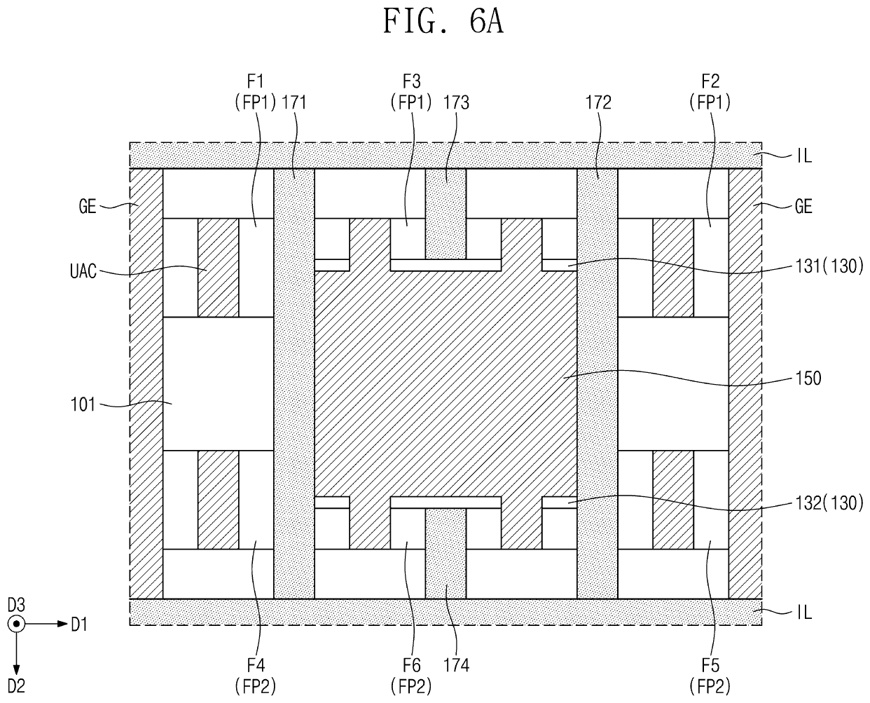

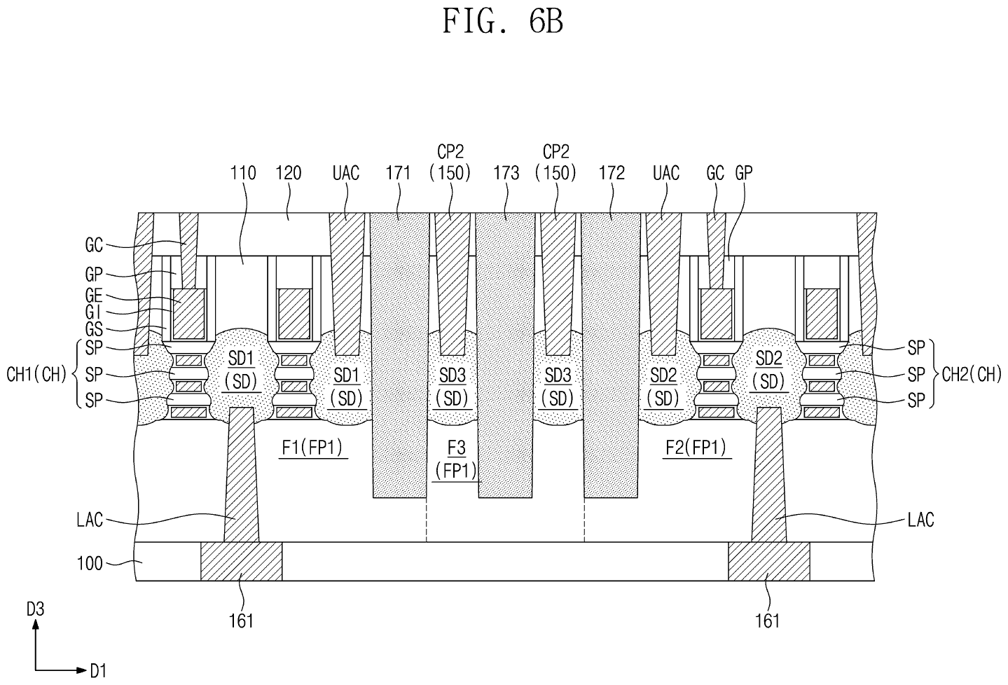

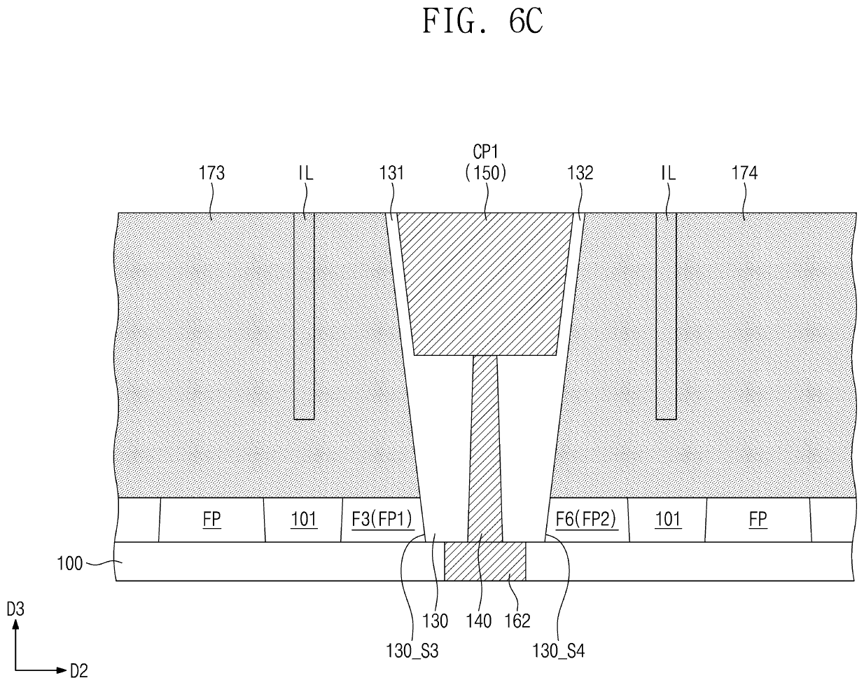

FIG. 6A is an enlarged cross-sectional view of a semiconductor device according to some embodiments. FIGS. 6B and 6C are cross-sectional views of the semiconductor device according to FIG. 6A. The semiconductor device according to FIGS. 6A, 6B, and 6C may be similar to the semiconductor device according to FIGS. 1A to 1G except for what is described below. FIG. 6A may correspond to FIG. 1F. FIG. 6B may correspond to FIG. 1B. FIG. 6C may correspond to FIG. 1E.

Referring to FIGS. 6A, 6B and 6C, the semiconductor device may include a third isolation structure 173 and a fourth isolation structure 174. The third isolation structure 173 and the fourth isolation structure 174 may be disposed between the first isolation structure 171 and the second isolation structure 172. The third isolation structure 173 may be disposed between the third source/drain patterns SD3. The third isolation structure 173 may be provided on the third fin portion F3. The fourth isolation structure 174 may be provided on the sixth fin portion F6.

The third isolation structure 173 and the fourth isolation structure 174 may be spaced apart from each other in the second direction D2. The insulating structure 130, the connection contact 140 and the upper conductive pattern 150 may be provided between the third isolation structure 173 and the fourth isolation structure 174. The third isolation structure 173 and the fourth isolation structure 174 may include the same insulating material as the first isolation structure 171 and the second isolation structure 172.

The third isolation structure 173 may be in contact with the third sidewall 130_S3 of the insulating structure 130. The fourth isolation structure 174 may be in contact with the fourth sidewall 130_S4 of the insulating structure 130. The first part 131 of the insulating structure 130 may be interposed between the third isolation structure 173 and the first pattern portion CP1 of the upper conductive pattern 150. The second part 132 of the insulating structure 130 may be interposed between the fourth isolation structure 174 and the first pattern portion CP1 of the upper conductive pattern 150.

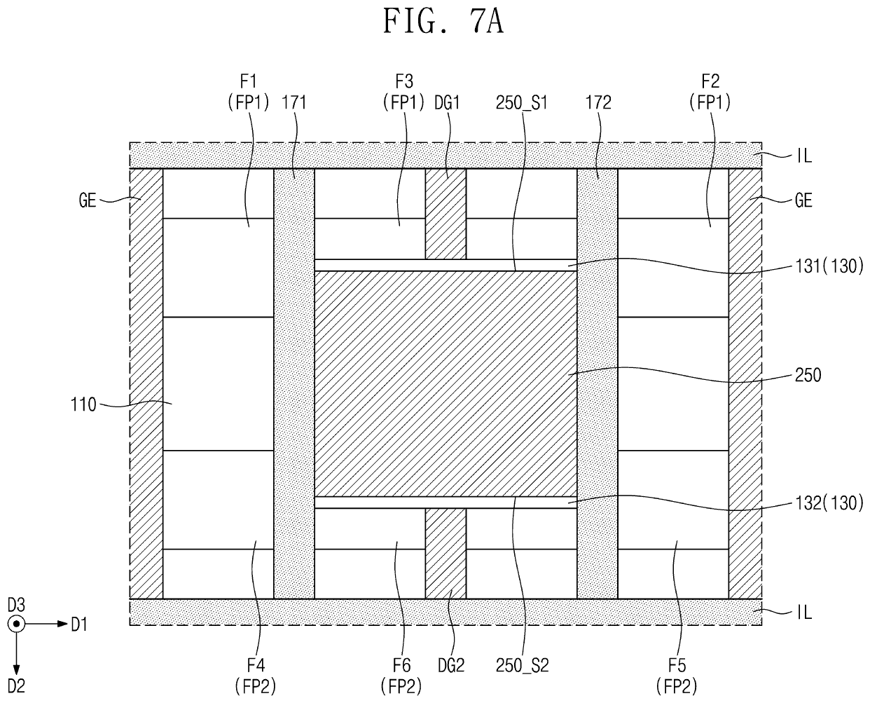

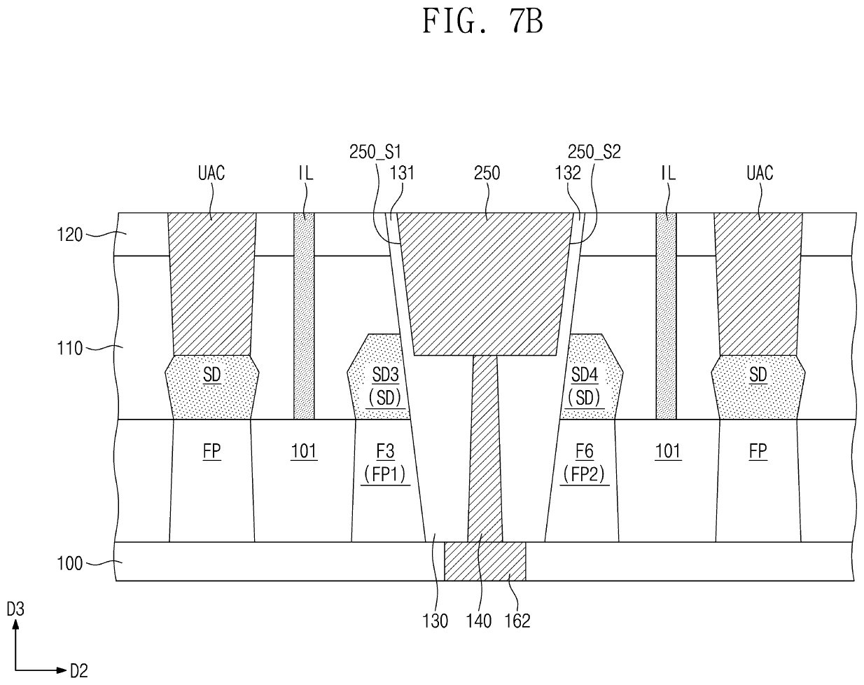

FIG. 7A is an enlarged cross-sectional view of a semiconductor device according to some embodiments. FIG. 7B is a cross-sectional view of the semiconductor device according to FIG. 7A. The semiconductor device according to FIGS. 7A and 7B may be similar to the semiconductor device according to FIGS. 1A to 1G except for what is described below. FIG. 7A may correspond to FIG. 1F. FIG. 7B may correspond to FIG. 1D.

Referring to FIGS. 7A and 7B, an upper conductive pattern 250 may be spaced apart from the third source/drain pattern SD3 and the fourth source/drain pattern SD4. The upper conductive pattern 250 may be electrically isolated from the third source/drain pattern SD3 and the fourth source/drain pattern SD4. The upper conductive pattern 250 may be spaced apart from the first interlayer insulating layer 110 and the second interlayer insulating layer 120. The upper conductive pattern 250 may be surrounded by the first and second isolation structures 171 and 172 and the first and second parts 131 and 132 of the insulating structure 130. The upper conductive pattern 250 may be disposed between the first and second parts 131 and 132 of the insulating structure 130.

The first part 131 of the insulating structure 130 may be disposed between the upper conductive pattern 250 and the second interlayer insulating layer 120, between the upper conductive pattern 250 and the first interlayer insulating layer 110, and between the upper conductive pattern 250 and the third source/drain pattern SD3.

The second part 132 of the insulating structure 130 may be disposed between the upper conductive pattern 250 and the second interlayer insulating layer 120, between the upper conductive pattern 250 and the first interlayer insulating layer 110, and between the upper conductive pattern 250 and the fourth source/drain pattern SD4.

A first sidewall 250_S1 of the upper conductive pattern 250 may be entirely in contact with the first part 131 of the insulating structure 130. A second sidewall 250_S2 of the upper conductive pattern 250 may be entirely in contact with the second part 132 of the insulating structure 130. The first sidewall 250_S1 and the second sidewall 250_S2 of the upper conductive pattern 250 may be opposed to each other.

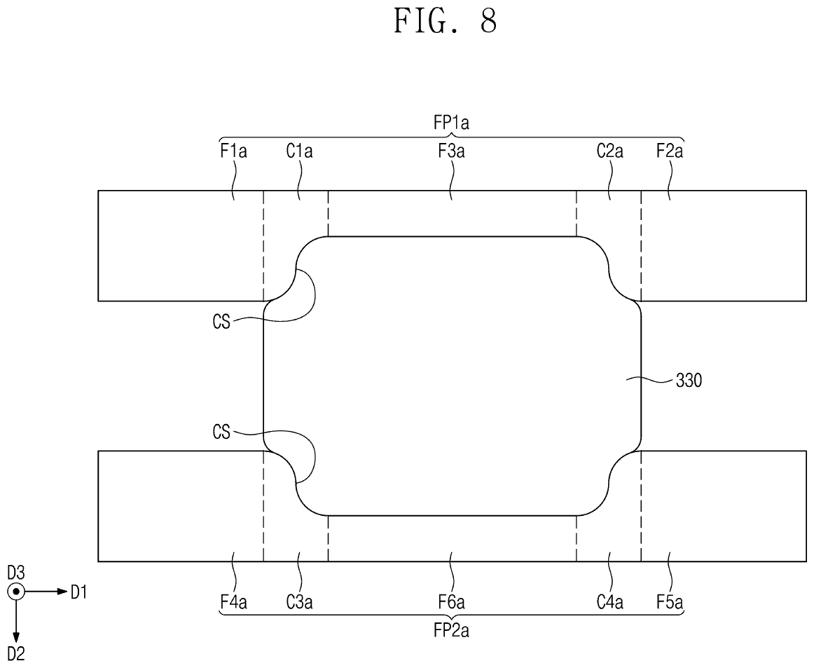

FIG. 8 is a plan view illustrating fin patterns and an insulating structure of a semiconductor device according to some embodiments. The semiconductor device according to FIG. 8 may be similar to the semiconductor device according to FIGS. 1A to 1G except for what is described below.

Referring to FIG. 8, the semiconductor device may include a first fin pattern FP1a and a second fin pattern FP2a spaced apart from each other. An insulating structure 330 may be provided between the first fin pattern FP1a and the second fin pattern FP2a.

The first fin pattern FP1a may include a first fin portion F1a, a second fin portion F2a, a third fin portion F3a, a first connection portion Cla and a second connection portion C2a. The third fin portion F3a, the first connection portion Cla and the second connection portion C2a may be disposed between the first fin portion F1a and the second fin portion F2a. The first connection portion Cla may be disposed between the first fin portion F1a and the third fin portion F3a. The second connection portion C2a may be disposed between the second fin portion F2a and the third fin portion F3a. The first to third fin portions Fla, F2a and F3a and the first and second connection portions Cla and C2a are separated and described but may be connected to each other without any boundaries and may have an integral structure.

A width in the second direction D2 of the third fin portion F3a may be smaller than a width in the second direction D2 of the first fin portion F1a and a width in the second direction D2 of the second fin portion F2a. A width in the second direction D2 of the first connection portion Cla may become greater as getting closer to the first fin portion F1a. A width in the second direction D2 of the first connection portion Cla may become smaller as getting closer to the third fin portion F3a. A width in the second direction D2 of the second connection portion C2a may become greater as getting closer to the second fin portion F2a. A width in the second direction D2 of the second connection portion C2a may become smaller as getting closer to the third fin portion F3a. The first connection portion Cla and the second connection portion C2a may each include a curved sidewall CS. The curved sidewall CS of each of the first connection portion Cla and the second connection portion C2a may be in contact with the insulating structure 330.

An isolation structure may be provided on the first connection portion Cla. An isolation structure may be provided on the second connection portion C2a.

The second fin pattern FP2a may include a fourth fin portion F4a, a fifth fin portion F5a, a sixth fin portion F6a, a third connection portion C3a and a fourth connection portion C4a. The sixth fin portion F6a, the third connection portion C3a and the fourth connection portion C4a may be disposed between the fourth fin portion F4a and the fifth fin portion F5a. The third connection portion C3a may be disposed between the fourth fin portion F4a and the sixth fin portion F6a. The fourth connection portion C4a may be disposed between the fifth fin portion F5a and the sixth fin portion F6a. The fourth to sixth fin portions F4a, F5a and F6a and the third and fourth connection portions C3a and C4a are separated and described but may be connected to each other without any boundaries and may have an integral structure.

A width in the second direction D2 of the sixth fin portion F6a may be smaller than a width in the second direction D2 of the fourth fin portion F4a and a width in the second direction D2 of the fifth fin portion F5a. A width in the second direction D2 of the third connection portion C3a may become greater as getting closer to the fourth fin portion F4a. A width in the second direction D2 of the third connection portion C3a may become smaller as getting closer to the sixth fin portion F6a. A width in the second direction D2 of the fourth connection portion C4a may become greater as getting closer to the fifth fin portion F5a. A width in the second direction D2 of the fourth connection portion C4a may become smaller as getting closer to the sixth fin portion F6a. The third connection portion C3a and the fourth connection portion C4a may each include a curved sidewall CS. The curved sidewall CS of each of the third connection portion C3a and the fourth connection portion C4a may be in contact with the insulating structure 330.

An isolation structure may be provided on the third connection portion C3a. An isolation structure may be provided on the fourth connection portion C4a.

The insulating structure 330 may be in contact with the first to fourth connection portions Cla, C2a, C3a and C4a, the third fin portion F3a and the sixth fin portion F6a. The insulating structure 330 may be in contact with the curved sidewalls CS of the first to fourth connection portions Cla, C2a, C3a and C4a. The insulating structure 330 may include curved sidewalls respectively corresponding to the curved sidewall CS.

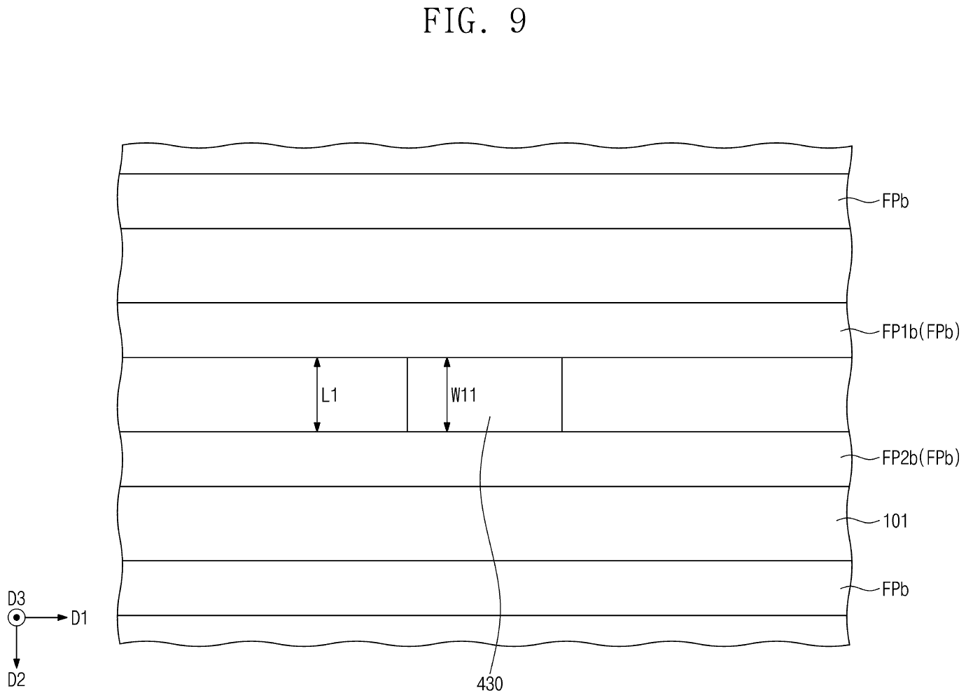

FIG. 9 is a plan view of a semiconductor device according to some embodiments. The semiconductor device according to FIG. 9 may be similar to the semiconductor device according to FIGS. 1A to 1G except for what is described below.

Referring to FIG. 9, fin patterns FPb may include a first fin pattern FP1b and a second fin pattern FP2b adjacent to each other in the second direction D2. An insulating structure 430 may be disposed between the first fin pattern FP1b and the second fin pattern FP2b. A width W11 in the second direction D2 of the insulating structure 430 may be the same as or smaller than a distance L1 in the second direction D2 between the first fin pattern FP1b and the second fin pattern FP2b.

According to some embodiments, the insulating structure 430 may be spaced apart from the first fin pattern FP1b and the second fin pattern FP2b. In a plan view according to FIG. 9, widths in the second direction D2 of the first fin pattern FP1b and the second fin pattern FP2b may be constant.

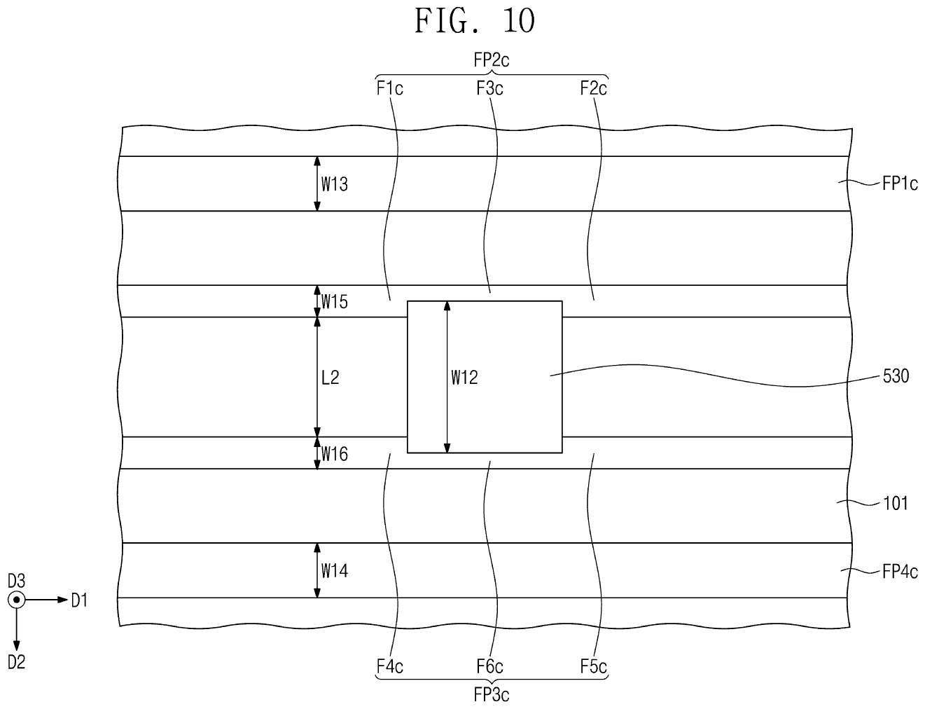

FIG. 10 is a plan view of a semiconductor device according to some embodiments. The semiconductor device according to FIG. 10 may be similar to the semiconductor device according to FIGS. 1A to 1G except for what is described below.

Referring to FIG. 10, a first fin pattern FP1c, a second fin pattern FP2c, a third fin pattern FP3c and a fourth fin pattern FP4c may be sequentially provided along the second direction D2. An insulating structure 530 may be disposed between the second fin pattern FP2c and the third fin pattern FP3c. A width W12 in the second direction D2 of the insulating structure 530 may be greater than a distance L2, in the second direction D2, between the second fin pattern FP2c and the third fin pattern FP3c.

The second fin pattern FP2c may include a first fin portion F1c, a second fin portion F2c and a third fin portion F3c. The third fin pattern FP3c may include a fourth fin portion F4c, a fifth fin portion F5c and a sixth fin portion F6c. The insulating structure 530 may be disposed between the third fin portion F3c and the sixth fin portion F6c.

A width W13 in the second direction D2 of the first fin pattern FP1c and a width W14 in the second direction D2 of the fourth fin pattern FP4c may be greater than a width W15 in the second direction D2 of the first fin portion F1c and a width W16 in the second direction D2 of the fourth fin portion F4c. A width in the second direction D2 of the third fin portion F3c may be smaller than the width W15 in the second direction D2 of the first fin portion F1c. A width in the second direction D2 of the sixth fin portion F6c may be smaller than the width W16 in the second direction D2 of the fourth fin portion F4c.

The width W13 in the second direction D2 of the first fin pattern FP1c may be the same as the width W14 in the second direction D2 of the fourth fin pattern FP4c. The width W15 in the second direction D2 of the first fin portion F1c may be the same as the width W16 in the second direction D2 of the fourth fin portion F4c.

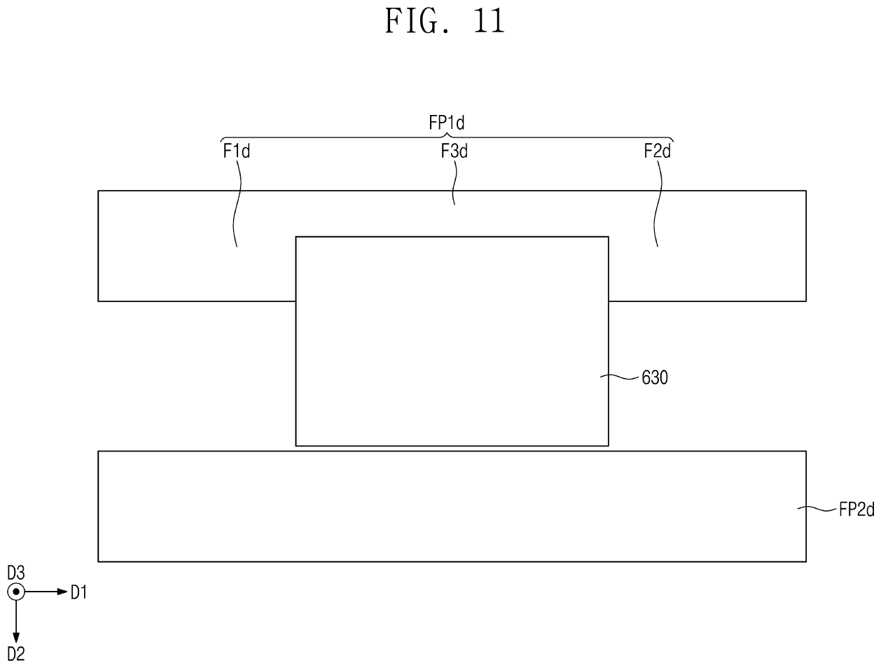

FIG. 11 is a plan view of a semiconductor device according to some embodiments. The semiconductor device according to FIG. 11 may be similar to the semiconductor device according to FIGS. 1A to 1G except for what is described below.

Referring to FIG. 11, the semiconductor device may include a first fin pattern FP1d and a second fin pattern FP2d spaced apart from each other. An insulating structure 630 may be provided between the first fin pattern FP1d and the second fin pattern FP2d.

The insulating structure 630 may be in contact with the first fin pattern FP1d. The insulating structure 630 may be spaced apart from the second fin pattern FP2d. The first fin pattern FP1d may include a first fin portion F1d, a second fin portion F2d and a third fin portion F3d. A width in the second direction D2 of the third fin portion F3d may be smaller than a width in the second direction D2 of the first fin portion F1d and a width in the second direction D2 of the second fin portion F2d. In a plan view according to FIG. 11, a width in the second direction D2 of the second fin pattern FP2d may be constant.

In a semiconductor device according to embodiments of the inventive concept, a fin pattern may include a fin portion having a relatively small width, and thus a phenomenon that a tensile stress occurs in the fin pattern may be prevented or limited. Accordingly, electrical characteristics of the semiconductor device may be improved.

Although the embodiments of the present invention have been described, it is understood that the present invention should not be limited to these embodiments but various changes and modifications can be made by one ordinary skilled in the art within the scope of the present invention as hereinafter claimed.

What is claimed is:

1. A semiconductor device comprising:
a first fin pattern extending in a first direction;
source/drain patterns on the first fin pattern;
a gate electrode extending in a second direction that intersects the first direction;
an insulating structure in contact with the first fin pattern;
a lower conductive pattern and an upper conductive pattern overlapping the insulating structure in a third direction that is perpendicular to the first and second directions; and
a connection contact extending through the insulating structure and electrically connecting the lower conductive pattern and the upper conductive pattern,
wherein the first fin pattern includes:
a first fin portion;
a second fin portion spaced apart from the first fin portion in the first direction; and
a third fin portion between the first fin portion and the second fin portion,
wherein a width in the second direction of the first fin portion and a width in the second direction of the second fin portion are greater than a width in the second direction of the third fin portion,
the insulating structure is between the first fin portion and the second fin portion, and
the insulating structure is in contact with the first fin portion, the second fin portion, and the third fin portion.

2. The semiconductor device of claim 1, further comprising:
a second fin pattern spaced apart from the first fin pattern in the second direction,
wherein the insulating structure is between the first fin pattern and the second fin pattern.

3. The semiconductor device of claim 2, wherein the second fin pattern comprises:
a fourth fin portion;
a fifth fin portion spaced apart from the fourth fin portion in the first direction; and
a sixth fin portion between the fourth fin portion and the fifth fin portion,
wherein a width in the second direction of the fourth fin portion and a width in the second direction of the fifth fin portion are greater than a width in the second direction of the sixth fin portion, and
the fourth fin portion, the fifth fin portion and the sixth fin portion are in contact with the insulating structure.

4. The semiconductor device of claim 1, further comprising:
a first channel structure overlapping the first fin portion in the third direction;
a second channel structure overlapping the second fin portion in the third direction; and
a dummy channel structure overlapping the third fin portion in the third direction,
wherein the dummy channel structure is in contact with the insulating structure.

5. The semiconductor device of claim 4, wherein a width in the second direction of the first channel structure and a width in the second direction of the second channel structure are greater than a width in the second direction of the dummy channel structure.

6. The semiconductor device of claim 1, wherein the source/drain patterns comprise:
a first source/drain pattern on the first fin portion;
a second source/drain pattern on the second fin portion; and
a third source/drain pattern on the third fin portion, and
the third source/drain pattern is in contact with the insulating structure.

7. The semiconductor device of claim 1, further comprising:
a first isolation structure and a second isolation structure on the first fin pattern and extending in the second direction,
wherein the insulating structure is between the first isolation structure and the second isolation structure.

8. The semiconductor device of claim 7, wherein a lower surface of the first isolation structure and a lower surface of the second isolation structure are farther from the lower conductive pattern than a lower surface of the insulating structure.

9. A semiconductor device comprising:
a first fin pattern extending in a first direction;
a gate electrode extending in a second direction that intersects the first direction;
an insulating structure in contact with the first fin pattern;
a lower conductive pattern and an upper conductive pattern overlapping the insulating structure in a third direction that is perpendicular to the first and second directions;
a connection contact extending through the insulating structure and electrically connecting the lower conductive pattern and the upper conductive pattern; and
a first source/drain pattern, a second source/drain pattern and a third source/drain pattern on the first fin pattern,
wherein the third source/drain pattern is between the first source/drain pattern and the second source/drain pattern, and
the third source/drain pattern is in contact with the insulating structure.

10. The semiconductor device of claim 9, wherein a width in the second direction of the first source/drain pattern and a width in the second direction of the second source/drain pattern are greater than a width in the second direction of the third source/drain pattern.

11. The semiconductor device of claim 9, wherein the upper conductive pattern comprises a first pattern portion in contact with the connection contact and a second pattern portion in contact with the third source/drain pattern.

12. The semiconductor device of claim 11, wherein a width in the second direction of the first pattern portion is greater than a width in the second direction of the second pattern portion, and
a width of the first pattern portion in the first direction perpendicular to the second direction is greater than a width of the second pattern portion in the first direction.

13. The semiconductor device of claim 9, further comprising:
a dummy gate electrode between the first source/drain pattern and the second source/drain pattern,
wherein the insulating structure is in contact with the dummy gate electrode.

14. The semiconductor device of claim 13, further comprising:
dummy semiconductor patterns overlapping the dummy gate electrode in the third direction,
wherein sidewalls of the dummy semiconductor patterns are in contact with the insulating structure.

15. The semiconductor device of claim 9, further comprising:
a second fin pattern spaced apart from the first fin pattern in the second direction; and
a fourth source/drain pattern on the second fin pattern,
wherein the upper conductive pattern is in contact with the third source/drain pattern and the fourth source/drain pattern.

16. The semiconductor device of claim 9, further comprising:
a lower insulating film in contact with a lower surface of the first fin pattern and a lower surface of the insulating structure,
wherein the lower conductive pattern is in the lower insulating film.

17. The semiconductor device of claim 16, further comprising:
a lower active contact at least partially penetrating the first fin pattern and connected to the first source/drain pattern.

18. A semiconductor device comprising:
a first fin pattern extending in a first direction;
a second fin pattern spaced apart from the first fin pattern in a second direction that intersects the first direction;
a gate electrode extending in the second direction;
source/drain patterns on the first and second fin patterns;
an insulating structure between the first fin pattern and the second fin pattern;
a lower conductive pattern and an upper conductive pattern overlapping the insulating structure in a third direction that is perpendicular to the first and second directions;
a connection contact extending through the insulating structure and electrically connecting the lower conductive pattern and the upper conductive pattern; and
a first isolation structure and a second isolation structure on the first fin pattern,
wherein the insulating structure, the connection contact and the upper conductive pattern are between the first isolation structure and the second isolation structure, and
the insulating structure is in contact with the first fin pattern and the second fin pattern.

19. The semiconductor device of claim 18, wherein the first fin pattern comprises:
a first fin portion;
a second fin portion spaced apart from the first fin portion in the first direction; and
a third fin portion between the first fin portion and the second fin portion,
wherein a width in the second direction of the first fin portion and a width in the second direction of the second fin portion are greater than a width in the second direction of the third fin portion, and
wherein the second fin pattern comprises:
a fourth fin portion;
a fifth fin portion spaced apart from the fourth fin portion in the first direction; and
a sixth fin portion between the fourth fin portion and the fifth fin portion,
wherein a width in the second direction of the fourth fin portion and a width in the second direction of the fifth fin portion are greater than a width in the second direction of the sixth fin portion, and
the insulating structure is between the third and sixth fin portions, between the first and second fin portions, and between the fourth and fifth fin portions.

20. The semiconductor device of claim 19, wherein the source/drain patterns comprise:
a first source/drain pattern on the first fin portion;
a second source/drain pattern on the second fin portion;
a third source/drain pattern on the third fin portion; and
a fourth source/drain pattern on the sixth fin portion,
wherein the third source/drain pattern and the fourth source/drain pattern are in contact with the insulating structure.
